(19) United States
(12) Patent Application Publication
(10) Pub. No.: US 2025/0246547 A1
(43) Pub. Date: Jul. 31, 2025

(54) SEMICONDUCTOR DEVICES AND DATA STORAGE SYSTEMS INCLUDING THE SAME

(71) Applicant: Samsung Electronics Co., Ltd., Suwon-si (KR)

(72) Inventors: Kohji Kanamori, Suwon-si (KR); Seogoo Kang, Suwon-si (KR); Junghoon Jun, Suwon-si (KR); Jeehoon Han, Suwon-si (KR)

(21) Appl. No.: 18/791,824

(22) Filed: Aug. 1, 2024

(30) Foreign Application Priority Data
Jan. 26, 2024 (KR) 10-2024-0012568

(51) Int. Cl. H01L 23/528; G11C 16/04; H01L 25/065; H10B 43/10; H10B 43/27; H10B 43/35; H10B 80/00

(52) U.S. Cl. CPC H01L 23/5283; G11C 16/0483; H01L 25/0652; H10B 43/10; H10B 43/27; H10B 43/35; H10B 80/00; H01L 2225/06506

(57) ABSTRACT

A semiconductor device includes a stack structure that defines a channel hole that extends in the first direction, a conductive structure on the stack structure, and a channel structure in the channel hole, where the channel structure includes: a channel dielectric layer on an inner surface of the channel hole, a channel layer that is on the channel dielectric layer, a first contact layer that contacts an inner surface of the channel layer and includes an impurity of a first conductivity-type, and a second contact layer that contacts an outer surface of the channel layer and includes an impurity of a second conductivity-type, where each of an upper surface of the first contact layer and an upper surface of the second contact layer contacts a lower surface of the conductive structure.

### CROSS-REFERENCE TO RELATED APPLICATION(S)

This application claims benefit of priority to Korean Patent Application No. 10-2024-0012568 filed on Jan. 26, 2024, in the Korean Intellectual Property Office, the disclosure of which is incorporated herein by reference in its entirety.

### TECHNICAL FIELD

The present disclosure relates to semiconductor devices and data storage systems including the same.

### BACKGROUND

In data storage systems that require data storage, semiconductor devices for storing high-capacitance data are desired. Accordingly, methods for increasing the data storage capacitance of semiconductor devices are being studied. For example, as one of the methods for increasing the data storage capacitance of a semiconductor device, a semiconductor device including memory cells arranged three-dimensionally instead of memory cells arranged two-dimensionally has been proposed.

### SUMMARY

An aspect of the present disclosure is to provide a semiconductor device having improved electrical characteristics and reliability.

An aspect of the present disclosure is to provide a data storage system including a semiconductor device having improved electrical characteristics and reliability.

According to an aspect of the present disclosure, provided is a semiconductor device including: a stack structure that includes gate electrodes spaced apart from each other in a first direction, where the stack structure defines a channel hole that extends in the first direction, where a width of an upper end of the channel hole in a second direction is greater than a width of a lower end of the channel hole in the second direction, and where the second direction is perpendicular to the first direction, a conductive structure on the stack structure, and a channel structure in the channel hole, where the channel structure includes: a channel dielectric layer on an inner surface of the channel hole, a channel layer that is on the channel dielectric layer, is in the channel hole, and extends from the upper end of the channel hole to the lower end of the channel hole, a first contact layer that contacts an inner surface of the channel layer and extends from the upper end of the channel hole in the first direction, where the first contact layer includes an impurity of a first conductivity-type, and a second contact layer that contacts an outer surface of the channel layer and extends from the upper end of the channel hole in the first direction, where the second contact layer includes an impurity of a second conductivity-type different from the first conductivity-type, and where each of an upper surface of the first contact layer and an upper surface of the second contact layer contacts a lower surface of the conductive structure.

Meanwhile, according to an aspect of the present disclosure, provided is a semiconductor device including: a stack structure that includes gate electrodes spaced apart from each other in a first direction, where the stack structure defines a channel hole that extends in the first direction, where a first width of an upper end of the channel hole in a second direction is greater than a second width of a lower end of the channel hole in the second direction, and where the second direction is perpendicular to the first direction, a conductive structure on the stack structure, and a channel structure in the channel hole, where the channel structure includes: a channel layer that is in the channel hole and extends between the upper end of the channel hole to the lower end of the channel hole, and a channel pad structure that is in the upper end of the channel hole and is electrically connected to the channel layer and the conductive structure, where the channel pad structure includes: a first contact layer that has the first width and includes an impurity of a first conductivity-type, a vertical insulating layer that at least partially surrounds a side surface of the first contact layer, where the channel layer at least partially surrounds an outer surface of the vertical insulating layer, and a second contact layer that at least partially surrounds an outer surface of the channel layer and includes an impurity of a second conductivity-type different from the first conductivity-type, where the first contact layer includes a portion that extends in the second direction, and where the vertical insulating layer is on and directly contacts the portion of the first contact layer.

Meanwhile, according to an aspect of the present disclosure, provided is a data storage system including a semiconductor storage device including a first semiconductor structure that includes circuit elements, a second semiconductor structure on a first surface of the first semiconductor structure, and an input/output pad electrically connected to the circuit elements, and a controller that is electrically connected to the semiconductor storage device by the input/output pad and is configured to control the semiconductor storage device, where the second semiconductor structure includes: a stack structure that includes gate electrodes spaced apart from each other in a first direction, a conductive structure on the stack structure a channel structure that extends into the stack structure and is in a channel hole, where an upper end of the channel hole has a first width in a second direction, where a lower end of the channel hole has a second width in the second direction, where the second direction is perpendicular to the first direction, and where the second width is greater than the first width, where the channel structure includes: a channel dielectric layer on an inner sidewall of the channel hole, a channel layer that is on the channel dielectric layer and extends between the upper end of the channel hole and the lower end of the channel hole, a first contact layer that contacts an inner surface of the channel layer, extends from the upper end of the channel hole in the first direction, and includes an impurity of a first conductivity-type, and a second contact layer that contacts an outer surface of the channel layer, extends from the upper end of the channel hole in the first direction, and includes an impurity of a second conductivity-type different from the first conductivity-type, where each of an upper surface of the first contact layer and an upper surface of the second contact layer contacts a lower surface of the conductive structure.

According to the present disclosure, a channel pad disposed on an upper surface of a channel structure of a semiconductor device may be implemented to include both a common source contact and a body selection contact, so that body erase (i.e., bulk erase) may be performed through the channel pad. Additionally, a horizontal conductive layer selectively providing a common source voltage and a body selection voltage may be disposed on a front surface of the semiconductor device, and an upper end of the channel structure in contact with the horizontal conductive layer may have a relatively wide width, thereby securing an area in which contacts having different conductivity-types may be disposed on a channel pad in an upper end thereof. Accordingly, a semiconductor device having improved reliability and integration and a data storage system including the same may be provided.

Advantages and effects of the present application are not limited to the foregoing content and may be more easily understood in the process of describing a specific example embodiment of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIGS. 1A and 1B are schematic plan views of a semiconductor device according to example embodiments;

FIGS. 2A and 2B are schematic cross-sectional views of a semiconductor device according to example embodiments;

FIG. 3 is a partially enlarged view of a semiconductor device according to example embodiments;

FIGS. 4A and 4B are conceptual diagrams illustrating a carrier path during operating of the semiconductor device of FIG. 3;

FIGS. 5, 6, and 7 are schematic cross-sectional views of a semiconductor device according to example embodiments;

FIG. 8 is a view schematically illustrating a data storage system including a semiconductor device according to example embodiments;

FIG. 9 is a schematic cross-sectional view of the data storage system of FIG. 8;

FIGS. 10, 11, 12A, 12B, 13A. 13B, 14A, 14B, 15A, 15B, 16A, 16B, 17A, 17B, 18A, 18B, 19A, 19B, 20A, 20B, 21, 22A, 22B, 23, and 24 are schematic cross-sectional views illustrating a method of manufacturing a semiconductor device according to example embodiments;

FIG. 25 is a view schematically illustrating a data storage system including a semiconductor device according to example embodiments;

FIG. 26 is a perspective view schematically illustrating a data storage system including a semiconductor device according to example embodiments; and

FIG. 27 is a cross-sectional view schematically illustrating a semiconductor package according to example embodiments.

### DETAILED DESCRIPTION

To clarify the present disclosure, parts that are not connected with the description will be omitted, and the same elements or equivalents are referred to by the same reference numerals throughout the specification. In the drawings, for better understanding and ease of description, thicknesses of some layers and areas are excessively displayed. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures.

As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection. The term “level of a surface” may refer to a distance between the surface and another reference component in a given direction. As such, a level of a first surface that is higher or greater than a level of a second surface refers to the first surface and a reference component being separated by a first distance, and a second surface and the reference component being separated by a second distance that is less than the first distance. Furthermore, a level of a first surface that is less than a level of a second surface refers to the first surface and a reference component being separated by a first distance, and a second surface and the reference component being separated by a second distance that is greater than the first distance.

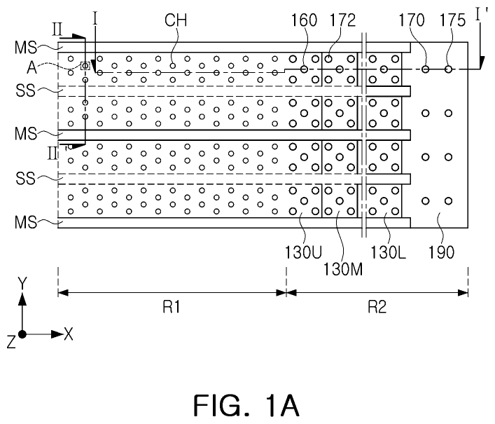

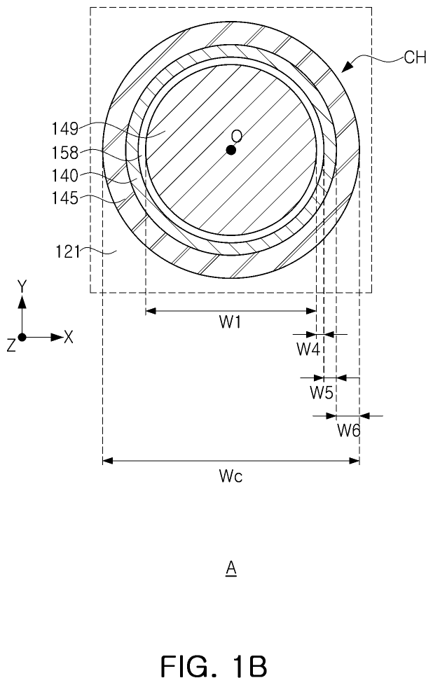

FIGS. 1A and 1B are schematic plan views of a semiconductor device according to example embodiments. FIG. 1B is an enlarged view of region ‘A’ of FIG. 1A.

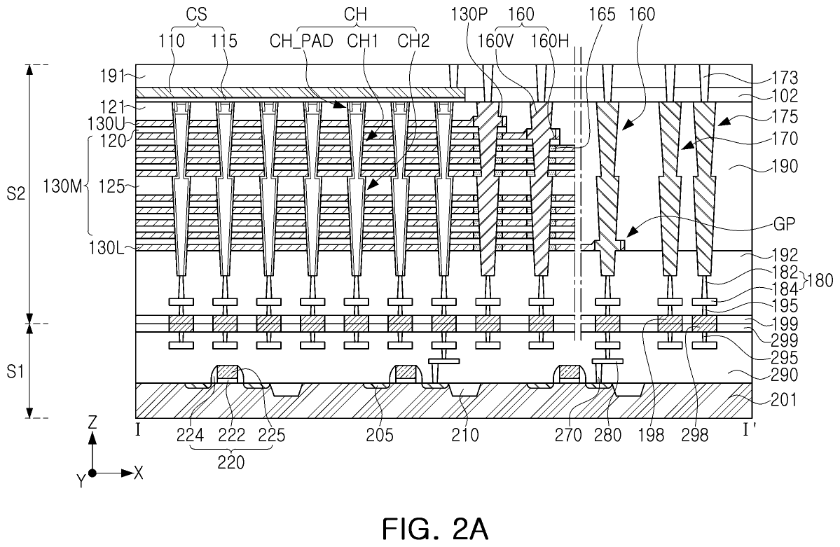

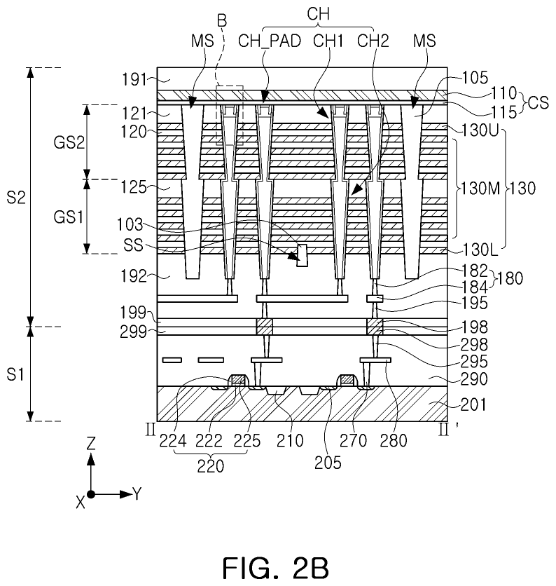

FIGS. 2A and 2B are schematic cross-sectional views of a semiconductor device according to example embodiments. FIGS. 2A and 2B are cross-sectional views taken along cutting lines I-I′ and II-II′ of FIG. 1A, respectively.

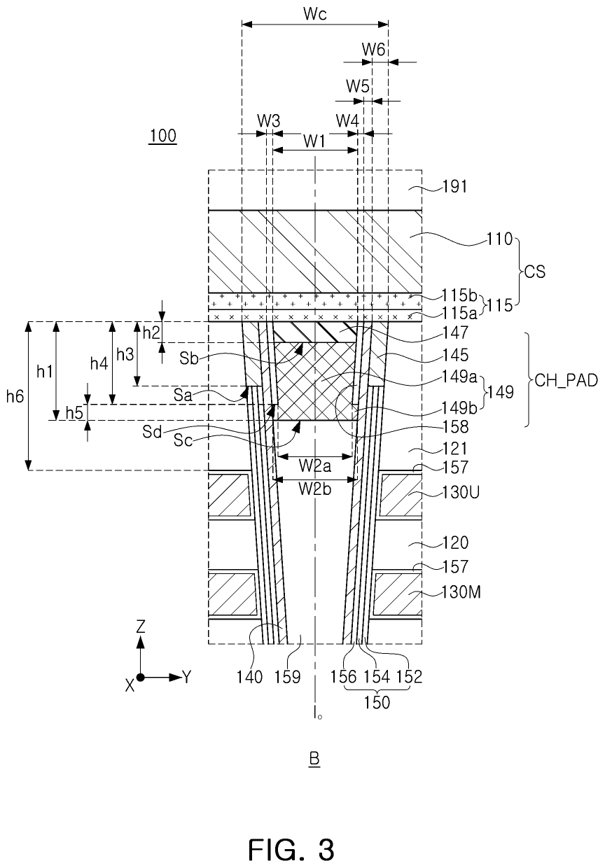

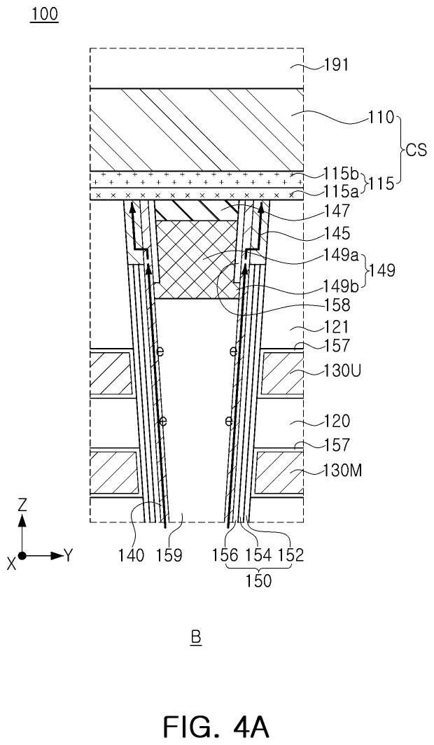

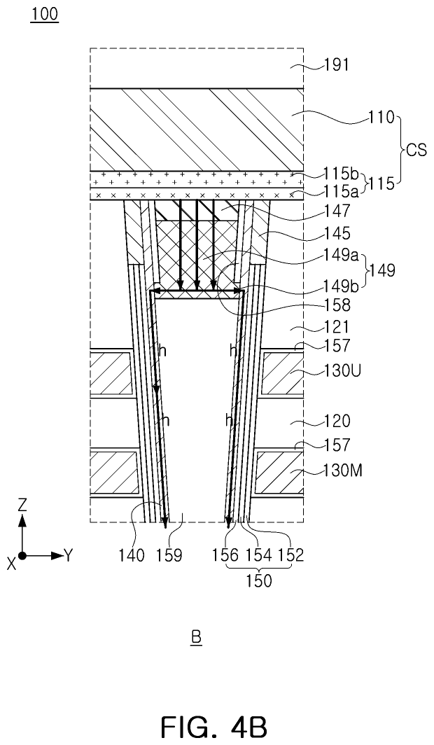

FIG. 3 is a partially enlarged view of a semiconductor device according to example embodiments. FIG. 3 is an enlarged view of region ‘B’ of FIG. 2B. FIGS. 4A and 4B are conceptual diagrams illustrating a carrier path during operating of the semiconductor device of FIG. 3.

Referring to FIGS. 1A to 3, a semiconductor device 100 includes first and second structures S1 and S2 stacked vertically. For example, the first structure S1 may include a peripheral circuit region PERI of the semiconductor device 100, and the second structure S2 may include a memory cell region CELL of the semiconductor device 100.

The first structure S1 may include a substrate 201, source/drain regions 205 and device isolation layers 210 inside the substrate 201, circuit elements 220 disposed on and/or in the substrate 201, circuit contact plugs 270, circuit interconnection lines 280, a peripheral region insulating layer 290, first bonding vias 295, and first bonding metal layers 298.

The substrate 201 may have an upper surface extending in an X-direction and a Y-direction. The device isolation layers 210 may be formed on the substrate 201 to define an active region. The source/drain regions 205 including impurities may be disposed in a portion of the active region. The substrate 201 may include a semiconductor material, such as a group IV semiconductor, a group III-V compound semiconductor, or a group II-VI compound semiconductor. For example, the substrate 201 may be provided as a single crystal bulk wafer.

The circuit elements 220 may include planar transistors. Each circuit element 220 may include a circuit channel dielectric layer 222, spacer layers 224, and a circuit gate electrode 225. The source/drain regions 205 may be disposed inside the substrate 201 on both sides of the circuit gate electrode 225.

The peripheral region insulating layer 290 may be disposed on the circuit element 220 on the substrate 201. The circuit contact plugs 270 and the peripheral region insulating layer 290 may form a first interconnection structure of the first structure S1. The circuit contact plugs 270 may have a cylindrical shape, and may be connected to the source/drain regions 205 by penetrating through or extending into the peripheral region insulating layer 290. An electrical signal may be applied to the circuit element 220 by the circuit contact plugs 270. In a region not illustrated, the circuit contact plugs 270 may also be connected to the circuit gate electrode 225. The circuit interconnection lines 280 may be connected to the circuit contact plugs 270, and may have a line or linear shape and may be arranged in a plurality of layers. In example embodiments, the circuit contact plugs 270 and the number of layers of circuit interconnection lines 280 may vary.

The first bonding vias 295 and first bonding metal layers 298 may constitute a first bonding structure and may be disposed on a portion of an uppermost circuit interconnection lines 280. Upper surfaces of the first bonding metal layers 298 may be exposed to an upper surface of the first structure S1. The first bonding vias 295 and the first bonding metal layers 298 may function as a bonding structure or a bonding layer of the first structure S1 and the second structure S2. Additionally, the first bonding vias 295 and the first bonding metal layers 298 may provide an electrical connection path with the second structure S2. In example embodiments, some of the first bonding metal layers 298 may not be connected to circuit interconnection lines 280 in a lower portion thereof and may be disposed only for bonding. The first bonding vias 295 and the first bonding metal layers 298 may include a conductive material, for example, copper (Cu).

In example embodiments, the peripheral region insulating layer 290 may include a bonding insulating layer 299 having a predetermined thickness from an upper surface thereof. The bonding insulating layer 299 may be a layer for dielectric-dielectric bonding with the bonding insulating layer 299 of the second structure S2. The bonding insulating layer 299 may also function as a diffusion barrier of the first bonding metal layers 298, and may include, for example, at least one of SiO, SiN, SiCN, SiOC, SiON, and SiOCN.

The second structure S2 may include a horizontal conductive structure CS disposed on a first region R1, gate electrodes 130 stacked on a lower surface of the horizontal conductive structure CS and spaced apart from each other in a Z-direction to form the gate structure GS, an interlayer insulating layers 120 alternately stacked with the gate electrodes 130, channel structures CH disposed to penetrate through or extend into the gate structure GS in the first region R1 and including a first channel portion CH1, a second channel portion CH2 and a channel pad CH_PAD, separation regions MS extending in one direction by penetrating through or extending into the gate electrodes 130, and lower insulating regions SS penetrating through or extending into a portion of the gate electrodes 130. The second structure S2 may further include a horizontal insulating layer 102 disposed in parallel with the horizontal conductive structure CS in a second region R2, a cell region insulating layer 190 covering or overlapping the gate electrodes 130, and a passivation layer 191 on the horizontal conductive structure CS. The second structure S2 may further include support structures 172, contact plugs 160, through-vias 170 and 175, and a cell interconnection structure 180. The second structure S2 may further include second bonding vias 195 and second bonding metal layers 198 as a second bonding structure.

In the second structure S2, which is the memory cell region, the first region R1 is a region in which the gate electrodes 130 are vertically stacked and channel structures CH are disposed, and may be a region in which the memory cells are disposed. In the second region R2, the gate electrodes 130 may extend to different lengths, and may correspond to a region for electrically connecting the memory cells to the first structure S1. The second region R2 may be disposed in at least one end of the first region R1 in at least one direction, for example, the X-direction.

The horizontal conductive structure CS may include a horizontal conductive layer 110 and a diffusion barrier 115, as a plate structure having an upper surface extending in the X-direction and the Y-direction in the first region R1. The horizontal conductive layer 110 may have an upper surface extending in the X-direction and the Y-direction. The horizontal conductive layer 110 may include a conductive material. The horizontal conductive layer 110 may include a metallic material, such as tungsten (W), aluminum (Al), or copper (Cu). The horizontal conductive structure CS may further include a diffusion barrier 115 below the horizontal conductive layer 110. The diffusion barrier 115 may include at least a double layer, and may include a metal barrier 115b in contact with the horizontal conductive layer 110 and a horizontal contact layer 115a below the metal barrier 115b. The metal barrier 115b may be used to prevent or inhibit metal particles of the horizontal conductive layer 110 at the top from diffusing into an interlayer insulating layer 121 at the bottom, and may include metal nitride. As an example, the metal barrier 115b may include tungsten nitride (WN), tantalum nitride (TaN), titanium nitride (TiN), or combination thereof. The horizontal contact layer 115a may be a low-resistance layer for forming ohmic contact between the horizontal conductive layer 110 and a semiconductor material at the bottom, and may include a metallic material, for example, titanium (Ti), but the present disclosure is not limited thereto. A thickness of the horizontal conductive layer 110 may be greater than a total thickness of the diffusion barrier 115, and a thickness of the metal barrier 115b of the diffusion barrier 115 may be greater than a thickness of the horizontal contact layer 115a.

The horizontal conductive structure CS may selectively function as a common source line CSL of the semiconductor device 100 depending on the applied voltage level, and may also function as a body voltage line BSL for bulk erase. The horizontal conductive structure CS may be physically and electrically connected to an upper surface of the channel pads CH_PAD on an upper portion of the channel structures CH, and specifically, the diffusion barrier 115, more specifically, upper surfaces of the horizontal contact layer 115a and the upper channel pads CH_PAD of the channel structures CH may be in direct contact therewith and be electrically connected thereto.

The horizontal insulating layer 102 may be disposed in parallel with the horizontal conductive structure CS in at least a portion of the second region R2. The horizontal insulating layer 102 may include silicon oxide, silicon nitride, silicon carbide, or silicon oxynitride.

A substrate insulating layer 192 may be disposed in a region in which lower ends of the channel structures CH, the contact plugs 160, and the through-vias 170 and 175, and the interconnection structures 180 are disposed, in a lower portion of a stack structure GS of the second structure S2. The substrate insulating layer 192 may include an insulating material, for example, silicon oxide, silicon nitride, silicon carbide, or silicon oxynitride.

The gate structure GS may include first and second gate structures GS1 and GS2 vertically stacked. However, according to example embodiments, the number of gate structures forming the gate structure GS may be changed variously. For example, in some example embodiments, the gate structure GS may be formed of two or more gate structures or may be formed of a single gate structure. The number of gate electrodes 130 forming each of the first and second gate structures GS1 and GS2 may be identical or different.

The gate electrodes 130 may include lower gate electrodes 130L forming string selection transistors, memory gate electrodes 130M forming a plurality of memory cells, and upper gate electrodes 130U forming a ground selection transistor. The number of memory gate electrodes 130M forming memory cells may be determined depending on the capacitance of the semiconductor device 100. One of the upper gate electrode 130U and the lower gate electrode 130L may also be referred to as an upper selection gate electrode and a lower selection gate electrode, respectively. According to some example embodiments, one to four or more upper gate electrodes 130U and lower gate electrodes 130L, respectively, may be provided, and the upper gate electrode 130U and the lower gate electrodes 130L may have the structures identical to or different from the memory gate electrodes 130M. In some example embodiments, the upper gate electrode 130U and/or at least one lower gate electrode 130L may be omitted. Some of the gate electrodes 130, for example, the memory gate electrodes 130M adjacent to the upper gate electrode 130U or the lower gate electrodes 130L, may be dummy gate electrodes.

The gate electrodes 130 are stacked to be vertically spaced apart from each other on the first region R1, and may extend from the first region R1 to the second region R2 at different lengths, thus forming step structures having a staircase configuration in gate pad regions GP. As illustrated in FIG. 2A, the gate electrodes 130 may have a shape in which a predetermined depth is removed from an upper portion of any one of the first to second gate structures GS1 and GS2 in the gate pad regions GP. The gate pad regions GP may be arranged so as not to overlap each other in the Z-direction. On the gate pad region GP of the first gate structure GS1, a least a portion of the gate electrodes 130 forming the second gate structures GS2 at the top may extend horizontally. In some example embodiments, the gate pad regions GP may be arranged in the second gate structure GS2 and the first gate structure GS1 in that order from the first region R1 in the X-direction. However, in example embodiments, the arrangement form, arrangement order, and depth of the gate pad regions GP may be changed variously. In some example embodiments, the gate electrodes 130 may not be disposed on the gate pad regions GP.

The gate electrodes 130 may form step structures in an asymmetrical form in each of the gate pad regions GP in the X-direction. A first step structure may be a staircase structure, disposed relatively adjacently to the first region R1, in which a level thereof decreases in the X-direction, and a second step structure may be a staircase structure, disposed relatively far from the first region R1, in which a level thereof increases in the X-direction. For example, in each gate pad region GP, a slope of the first step structure may be smaller than a slope of the second step structure in the first region R1. However, in some example embodiments, the first and second step structures may have symmetrical shapes. In the first step structure, the gate electrodes 130 may be connected to contact plugs 160, and in the second step structure, the gate electrodes 130 may form a dummy region or a support structure that is not connected to the contact plugs 160. In example embodiments, a specific shape of the step structure, the number of gate electrodes 130 forming each step structure, and the like, are not limited to the form illustrated in FIG. 2A. In some example embodiments, the gate electrodes 130 may be arranged to have a step structure in the Y-direction.

As illustrated in FIG. 2A, due to the first step structure, the gate electrodes 130 may be formed so that a gate electrode 130 in a lower portion thereof extends longer than a gate electrode 130 in an upper portion thereof, each of which may have contact regions 130P exposed upwardly from the interlayer insulating layers 120. The gate electrodes 130 may be respectively connected to the contact plugs 160 in the contact regions 130P, which are end regions. The gate electrodes 130 may have an increased thickness in the contact regions 130P. The gate electrodes 130 may include the first region R1 so that a thickness thereof in the contact region 130P may be greater than a thickness thereof in a region in which the other gate electrodes 130 are disposed on an upper surface.

The gate electrodes 130 may include a metallic material, for example, tungsten (W). According to some example embodiments, the gate electrodes 130 may include polycrystalline silicon or a metal silicide material. The gate electrodes 130 may include the same material as a whole. In example embodiments, the gate electrodes 130 may further include a horizontal blocking layer 157 as a diffusion barrier, and for example, the diffusion barrier may include tungsten nitride (WN), tantalum nitride (TaN), titanium nitride (TiN), or combination thereof.

The interlayer insulating layers 120 may be disposed between the gate electrodes 130. Similarly to the gate electrodes 130, the interlayer insulating layers 120 may be spaced apart from each other in a direction, perpendicular to a lower surface of the horizontal conductive structure CS, and may be arranged to extend in the X-direction. The interlayer insulating layers 120 may include an insulating material such as silicon oxide or silicon nitride. Among the interlayer insulating layers 120, an interlayer insulating layer 125 between respective gate structure GS1 and GS2 may have a greater thickness than the other interlayer insulating layers 120, and an uppermost interlayer insulating layer 121 may also have a greater thickness than the other interlayer insulating layers 120, but the present disclosure is not limited thereto.

Each of the channel structures CH may form one memory cell string, and may be spaced apart from each other by forming rows and columns below the horizontal conductive layer 110 in the first region R1. The channel structures CH may be disposed to form a grid pattern in an X-Y plane or may be disposed in a zigzag shape in one direction. The channel structures CH may have a pillar shape, and depending on an aspect ratio, widths of the channel structures CH may be reduced as they move away from the horizontal conductive layer 110, so that the channel structures CH may have inclined side surfaces. According to example embodiments, at least some of the channel structures CH disposed in an end of the first region R1 may be dummy channel structures.

Each of the channel structures CH may include a first channel portion CH1, a second channel unit CH2, and a channel pad CH_PAD, which are vertically stacked and connected to each other. The first channel portion CH1 and the second channel portion CH2 may have bent portions in a region or an interface in which the first channel portion CH1 and the second channel portion CH2 are connected to each other, in a form in which a width of an upper surface of a channel portion disposed at the bottom is larger than a width of a lower surface of a channel portion disposed at the top. As each of the first channel portion CH1 and the second channel portion CH2 moves downwardly, that is, as it moves away from the horizontal conductive layer 110, a width thereof may decrease, so that side surfaces thereof may have a slope. The first channel portions CH1 of the two channel structures CH on both sides of a lower insulating region SS have the smallest width, thus securing a space in which the lower insulating region SS may be formed.

As the first channel portion CH1 moves downwardly, that is, as it moves away from the horizontal conductive layer 110, a width of an upper surface thereof may decrease, so that side surfaces thereof may have a slope. An end of the first channel portion CH1 may protrude or extend downwardly by penetrating through or extending into a lowermost gate electrode 130L, and may be connected to a lower stud 182 and connected to lower interconnections 184. As the second channel portion CH2 moves downwardly from an upper surface thereof, that is, as it moves away from the horizontal conductive layer 110, a width thereof may decrease, so that side surfaces thereof may have a slope. The channel pad CH_PAD may be disposed in an upper end of the second channel portion CH2 having the largest width.

Each of the channel structures CH may include a channel layer 140, a channel dielectric layer 150, a channel buried insulating layer 159, and a channel pad CH_PAD, disposed inside the channel hole. The channel layer 140, the channel dielectric layer 150, and the channel buried insulating layer 159 may be connected to each other between the first and second channel portions CH1 and CH2.

As illustrated in an enlarged view of FIG. 3, the channel layer 140 may be formed in an annular shape and at least partially surround an internal channel-filled or channel-buried insulating layer 159, but according to some example embodiments, the channel layer 140 may have a pillar shape such as a cylinder or a prism without the channel buried insulating layer 159. The channel layer 140 may be connected to the horizontal conductive structure CS through the channel pad CH_PAD in an upper portion of the channel hole. The channel layer 140 may include a semiconductor material such as polycrystalline silicon or single crystalline silicon.

The channel layer 140 may be a layer that is not doped with conductive impurities such as P-type or N-type impurities during a manufacturing process. That is, the channel layer 140 may be a layer that is not intentionally doped with conductive impurities. However, in some example embodiments, the channel layer 140 may further include n-type impurities or P-type impurities diffused from the first contact layer 149, the second contact layer 145, and a lower contact (not illustrated), in an upper region and/or a lower region. The channel layer 140 may be formed to have a predetermined thickness W5 on the X-Y plane, perpendicular to the Z-direction on a side surface of the channel hole, and may extend continuously from the upper end to the lower end of the channel hole. The thickness W5 of the channel layer 140 may be between 5 nm and 10 nm, for example, about 6 nm, but the present disclosure is not limited thereto.

The channel dielectric layer 150 may be disposed between the gate electrodes 130 and the channel layer 140. The channel dielectric layer 150 may be disposed to cover or overlap an inner surface of the channel hole in which the channel structure CH is disposed. The channel dielectric layer 150 may include a blocking layer 152, a charge storage layer 154, and a tunneling layer 156 stacked in order from the gate electrodes 130. The semiconductor device 100 may further include a horizontal blocking layer 157, and the horizontal blocking layer 157 may extend along the gate electrodes 130 in a horizontal direction. In some example embodiments, the horizontal blocking layer 157 may be omitted.

The blocking layer 152 and the horizontal blocking layer 157 may include silicon oxide (SiO₂), silicon nitride (Si₃N₄), silicon oxynitride (SiON), a high-K dielectric material, or combinations thereof. The charge storage layer 154 may be a charge trap layer or a floating gate conductive layer. The tunneling layer 156 may tunnel charges into the charge storage layer 154, and may include, for example, silicon oxide (SiO₂), silicon nitride (Si₃N₄), silicon oxynitride (SiON), or combinations thereof.

The blocking layer 152, the charge storage layer 154, and the tunneling layer 156, which form the channel dielectric layer 150, may be formed to have a predetermined thickness W6, and may be spaced apart from an upper end of the channel hole by a predetermined distance h3 and may continuously extend to the lower end of the channel hole. The thickness W6 of the channel dielectric layer 150 may be between 16 nm and 20 nm, for example, may be about 18 nm, and each layer 152, 154, and 156 may have a similar thickness, but the present disclosure is not limited thereto.

The channel buried insulating layer 159 may be disposed inside the channel layer 140 to be spaced from the upper end of the channel hole by a predetermined distance h1 and fill or be in the channel hole up to the lower end of the channel hole. The channel buried insulating layer 159 may include an insulating material, and may include, for example, silicon oxide (SiO₂), silicon nitride (Si₃N₄), silicon oxynitride (SiON), or combinations thereof.

The channel pad CH_PAD may be disposed on an upper end of the channel structure CH. The channel pad CH_PAD may include a first contact layer 149 connected to the channel layer 140 and disposed in a center region of the channel hole, and a second contact layer 145 spaced apart from the first contact layer 149, at least partially surrounding the first contact layer 149, and disposed in an outer region of the channel hole.

Referring to FIGS. 1B and 3, when an upper surface of the channel hole has a circular shape, a diameter passing through a center (O) of a circle of the channel hole, that is, a width of an upper end of a channel structure, may be defined as a channel width Wc. The channel width Wc may be in a range of 100 nm to 120 nm, and may be, for example, around 110 nm. A Z-direction axis passing through the center (O) of the channel hole may be defined as a central axis Io.

The first contact layer 149 may be disposed to have a first width W1 in the upper end of the channel hole based on the central axis lo. The first contact layer 149 may include a vertical portion 149a and a horizontal portion 149b. The vertical portion 149a may fill a space from the upper end of the channel hole to an upper surface of the channel buried insulating layer 159, and may have a pillar type extending in the Z-direction to have a predetermined length h1. The horizontal portion 149b may be formed on a side surface of a lower portion of the vertical portion 149a, and may be an expanded region that protrudes in a circumferential direction such that a lower portion of the first contact layer 149 is expanded from a first lower width W2a to a second lower width W2b on the upper surface of the channel buried insulating layer 159. Accordingly, a lower surface of the vertical portion 149a and a lower surface of the horizontal portion 149b may be in contact with the upper surface of the channel buried insulating layer 159 to form a coplanar surface, thereby forming a lower surface Sc of the first contact layer 149.

The horizontal portion 149b may have an expansion length h5 in the Z-direction on a level spaced apart from the upper end of the channel hole by a separation distance h4 in the Z-direction, and may have a ring shape with an expansion width W3 in the circumferential direction. The horizontal portion 149b may be expanded toward the channel layer 140 so that an outer surface of the horizontal portion 149b is in direct contact with an inner surface of the channel layer 140, thereby forming a movement path for a hole in the first contact layer 149.

A level of the lower surface Sc of the first contact layer 149 may be equal to or higher than a level of an upper surface of an uppermost gate electrode 130U relative to, for example, the interconnection structure 180 (or lower relative to the horizontal conductive structure CS), and accordingly, a level of an upper surface of the horizontal portion 149b may be higher than a level of an upper surface of the uppermost gate electrode 130U relative to, for example, the interconnection structure 180 (or lower relative to the horizontal conductive structure CS). Accordingly, when the first contact layer 149 is in direct physical contact with the channel layer 140 at a height that does not horizontally overlap the gate electrode 130 and performs bulk erase, the holes may be injected into the channel layer 140.

A separation space may be formed between the vertical portion 149a and the channel layer 140 by the expansion width W3 of the horizontal portion 149b of the first contact layer 149, and the vertical insulating layer 158 may be disposed inside the separation space. The vertical insulating layer 158 may extend from the upper end of the channel hole by a predetermined length h4 in the Z-direction and may have a ring shape at least partially surrounding an outer surface of the vertical portion 149a.

The vertical insulating layer 158 may have a width W4 of the same size as the width W3 of the horizontal portion 149b, and may be formed so that an upper surface and a lower surface Sd of the horizontal portion 149b are in contact with each other, thus physically and electrically disconnecting the vertical portion 149a and the channel layer 140 overlapping each other in the horizontal direction, which is perpendicular to the Z-direction.

The width W4 of the vertical insulating layer 158 may be equal to or smaller than the thickness W5 of the channel layer 140, and may be, for example, about ⅓ of the thickness W5 of the channel layer 140, about 2 nm, but the present disclosure is not limited thereto. The vertical insulating layer 158 may include silicon oxide, silicon nitride, silicon carbide, or silicon oxynitride.

The first contact layer 149 may include a conductive material such as a polycrystalline semiconductor, e.g., polysilicon. The vertical portion 149a may include a doped region 147 having a predetermined length h2 in the Z-direction in an upper end thereof. The doped region 147 may be formed to have a depth of a predetermined length h2 from the upper end of the channel hole, and may include a region doped with an impurity of a first conductivity-type, so as to transfer holes to the channel layer 140 by erase voltage for bulk erase to form ohmic contact with the horizontal contact layer 115a. Accordingly, the doped region 147 may be doped with P-type impurities depending on a level of the erase voltage, and may be a highly doped region with a concentration of 10¹⁹/cm³ or more. The predetermined length h2 of the doped region 147 may be smaller than the length h4 of the vertical insulating layer 158, and a level of a lower surface Sb of the doped region 147 may be higher than a level of a lower surface Sd of the vertical insulating layer 158 and higher than a level of the upper surface of the uppermost gate electrode 130U. The first contact layer 149 may maintain a generally undoped state except for the doped region 147.

The second contact layer 145 may be disposed to be physically and electrically spaced apart from the doped region 147 by the vertical insulating layer 158. The second contact layer 145 may be disposed between an inner surface of the channel hole and an outer surface of the channel layer 140 with a predetermined length h3 from the upper end of the channel hole in the Z-direction. The second contact layer 145 may have a ring shape at least partially surrounding the outer surface of the channel layer 140, and a thickness W6 on the plane (X-Y plane) may be greater than the thickness W5 of the channel layer 140. The second contact layer 145 may be disposed on the channel dielectric layer 150 so that a lower surface Sa of the second contact layer 145 and an upper surface of the channel dielectric layer 150 are in contact with each other. Accordingly, a thickness of the channel dielectric layer 150 and the thickness W5 of the second contact layer 145 may be equal to each other, and may be about 10 nm to 20 nm, for example, about 18 nm, but the present disclosure is not limited thereto.

The second contact layer 145 may include a conductive material such as a polycrystalline semiconductor, e.g., polysilicon, and may include an impurity of a second conductivity-type different from the first conductivity-type of the doped region 147. For example, when N-type impurities are doped and a common voltage is applied, ohmic contact may be formed with the horizontal contact layer 115a according to the common voltage level, and electrons may be implanted into the channel layer 140 to induce inversion of the channel layer 140. Depending on the length h3 of the second contact layer 145, a level of the lower surface Sa of the second contact layer 145 may be higher than a level of the lower surface Sd of the vertical insulating layer 158, and may be higher than the level of the upper surface of the uppermost gate electrode 130U. Additionally, the level of the lower surface Sa of the second contact layer 145 may be equal to or lower than a level of a lower surface Sb of the doped region 147, but the present disclosure is not limited thereto.

In this manner, the horizontal portion 149b of the first contact layer 149 and the second contact layer 145 may be in direct contact with the inner surface and the outer surface of the channel layer 140, respectively, and may selectively provide holes or electrons to the channel layer 140 depending on the voltage level of the horizontal conductive layer 110. Additionally, the first contact layer 149 and the second contact layer 145 may be physically/electrically spaced apart from each other by the vertical insulating layer 158, and may prevent or inhibit impurities from diffusing during heat treatment for doping and activation of each different conductivity-type impurity. Accordingly, device reliability may be secured and driving stability may be ensured. In this manner, the first contact layer 149 for a P-type contact may be disposed in the center region of the channel pad CH_PAD of the channel structure CH, and the second contact layer 145 for an N-type contact may be disposed in a circumferential region, thus selectively transferring carriers from the horizontal conductive layer 110 to the channel layer 140.

The upper surfaces of the first contact layer 149, the second contact layer 145, and the vertical insulating layer 158 therebetween may be coplanar with each other, and may simultaneously come into contact with a lower portion of the horizontal conductive structure CS, for example, the horizontal contact layer 115a.

As illustrated in FIG. 1B, when viewed from above, in the channel pad CH_PAD, the doped region 147, which is an upper end of the first contact layer 149 with a first width W1, may be disposed in a center O thereof, the vertical insulating layer 158 at least partially surrounding a side surface of the first contact layer 149 and having a predetermined width W4 may be disposed in a ring type, the channel layer 140 at least partially surrounding an outer surface of the vertical insulating layer 158 and having a predetermined width W5 may be disposed in a ring type, and the second contact layer 145 at least partially surrounding the outer surface of the channel layer 140 and having a predetermined width W6 may be disposed in a ring type, thereby filling or being in the channel hole.

In this manner, since the channel layer 140 is in contact with the horizontal conductive structure CS through the first contact layer 149 and the second contact layer 145 in the channel pad CH_PAD in a state in which an electrical connection may be simultaneously conducted, the channel layer 140 may be selectively electrically connected to specific contact layers 149 and 145 to allow current to flow depending on the voltage applied to the horizon″al c'nductive structure CS.

Specifically, as illustrated in FIG. 4A, ground voltage may be applied to the horizontal conductive layer 110 during a read operation. The second contact layer 145 doped with N-type impurities, which is a second conductivity-type, and the horizontal conductive structure CS may be in ohmic contact with each other, and by inducing an inversion in the channel layer 140, electrons may be introduced through the channel layer 140 and information on a cell corresponding to the gate electrode 130 may be read.

Meanwhile, during a bulk erase operation, a positive voltage may be applied to the horizontal conductive layer 110, as illustrated in FIG. 4B, and holes may flow into the channel layer 140 through the first contact layer 149 doped with a P-type impurity, which is a first conductivity-type, and an erasing operation of the channel dielectric layer 150 may be performed.

In this manner, in the channel pad CH_PAD, the second contact layer 145 doped with N-type impurities and the first contact layer 149 doped with P-type impurities may simultaneously come into contact with each other between the horizontal conductive layer 110 and the channel layer 140, and may be selectively electrically connected to each other depending on voltage applied to the horizontal conductive layer 110, thus performing a required operation.

Specifically, by enabling bulk erase, it may be possible to perform an erase operation at a faster rate as compared to performing an erase operation of the channel layer 140 using a conventional erase transistor (GIDL TR) utilizing gate-drain leakage current, and may secure memory capacitance by operating without an erase transistor.

The separation regions MS may be disposed to extend in the X-direction by penetrating through or extending into at least some of the gate electrodes 130. As illustrated in FIG. 1A, the separation regions MS may be disposed in parallel with each other. As illustrated in FIG. 2B, the separation regions MS may penetrate through or extend into the gate electrodes 130 and be connected to a substrate insulating layer 192 below.

Some of the separation regions MS may extend into one along the first region R1 and the second region R2, the others thereof may extend only to a portion of the second region R2, or may be intermittently disposed in the first region R1 and the second region R2. However, in the example embodiments, the arrangement form and the number of separation regions MS are not limited to those illustrated in FIG. 1A.

A gate separation insulating layer 105 may be disposed in each of the separation regions MS. The gate separation insulating layer 105 may have a shape whose width decreases toward the lower horizontal insulating layer 193 due to a high aspect ratio thereof. The separation regions MS may have a bent shape at an interface of the gate structures GS. The gate separation insulating layer 105 may include an insulating material, for example, silicon oxide, silicon nitride, or silicon oxynitride.

The lower insulating regions SS may extend in the X-direction between adjacent separation regions MS, as illustrated in FIG. 1A. As the lower insulating regions SS move downwardly in the Z-direction, that is, as they move away from the horizontal conductive layer 110, a width thereof may increase, so that side surfaces thereof may have a slope. The lower insulating regions SS may have a slope direction opposite to a slope direction of the channel structures CH. Specifically, the lower insulating regions SS may have a slope direction opposite to a slope direction of the first channel portion CH1 and the second channel portion CH2, and may be disposed in a separation space between the first channel portions CH1 in two neighboring channel structures CH. The lower insulating regions SS may penetrate through or extend into at least one lower gate electrode 130L among the lower gate electrodes 130L between the first channel portion CH1. Accordingly, a width of an upper surface of the lower insulating regions SS may be smaller than a width of a lower surface thereof. The lower insulating regions SS may divide the lower gate electrode 130L in the Y-direction, as illustrated in FIGS. 2A and 2B.

Each of the lower insulating regions SS may include a lower separation insulating layer 103. The lower separation insulating layer 103 may include an insulating material, for example, silicon oxide, silicon nitride, or silicon oxynitride.

The contact plugs 160 may be connected to the contact regions 130P of the gate electrodes 130 in the gate pad regions GP of the second region R2. The contact plugs 160 may penetrate through or extend into at least a portion of the cell region insulating layers 190, and may be connected to each of the contact regions 130P of the upwardly exposed gate electrodes 130. The contact plugs 160 may penetrate through or extend into the gate electrodes 130 below the contact regions 130P and may be connected to interconnection lines 184. The contact plugs 160 may be spaced apart from the gate electrodes 130 below the contact regions 130P by contact insulating layers 165. However, in some example embodiments, the contact plugs 160 may be disposed so as not to penetrate through or extend into the gate electrodes 130, and in this case, the contact plugs 160 may be connected to each of the contact regions 130P of the upwardly exposed gate electrodes 130.

The contact plugs 160 may have a shape corresponding to the channel structures CH or a shape corresponding to the separation region MS. Each of the contact plugs 160 may include an upper region penetrating through or extending into the first and second gate structures GS1 and GS2, respectively, and a lower region extending from the upper region and disposed below the upper region. The lower region and the upper region may have inclined side surfaces in which a width thereof decreases as the lower region and the upper region move downwardly from each gate structure GS due to an aspect ratio, and may have a cylindrical shape. A slope direction of the upper region and the lower region of each gate structure GS may be opposite to a slope direction of the lower insulating region SS.

As illustrated in FIG. 2A, each of the contact plugs 160 may have a shape expanded horizontally in the contact region 130P. The contact plug 160 may include a vertical extension portion 160V extending in the Z-direction and a horizontal extension portion 160H extending horizontally from the vertical extension portion 160V and in contact with the gate electrode 130. The horizontal extension portion 160H may be disposed along a circumference of the vertical extension portion 160V, and an entire side surface thereof may be at least partially surrounded by the gate electrode 130. A length from a side surface of the vertical extension portion 160V to an end of the horizontal extension portion 160H may be smaller than a length from the side surface of the vertical extension portion 160V to outer surfaces of the contact insulating layers 165. The contact plugs 160 may be spaced apart from the gate electrodes 130 below the contact regions 130P, that is, gate electrodes 130 that are not electrically connected by the contact insulating layers 165.

The contact plugs 160 may include a conductive material, for example, at least one of tungsten (W), copper (Cu), aluminum (Al), and an alloy thereof. In some example embodiments, the contact plugs 160 may include a barrier layer extending along a side surface and a bottom surface thereof, or may have an air gap therein.

The contact insulating layers 165 may be disposed to at least partially surround a side surface of each of the contact plugs 160 below the contact regions 130P. The contact insulating layers 165 may be spaced apart from each other in the Z-direction around each of the contact plugs 160. The contact insulating layers 165 may be disposed at substantially the same level as the gate electrodes 130. The contact insulating layers 165 may include an insulating material, for example, silicon oxide, silicon nitride, or silicon oxynitride.

The support structures 172 may be disposed around the contact plugs 160. As illustrated in FIG. 1A, the support structures 172 may be disposed in a circular shape in the second region R2 in a plan view, and may be disposed in a regular shape around the contact plugs 160. For example, four support structures 172 may be arranged around one contact plug 160, but the present disclosure is not limited thereto. The support structures 172 may be continuously and regularly disposed in regions in which the contact plugs 160 are spaced apart from each other in the X-direction. The support structures 172 are not limited to circular shapes in a plan view, and may have various shapes such as polygons and ellipses.

The support structures 172 may penetrate through or extend into the gate structures GS to have the same shape as the contact plugs 160, and may have a cylindrical shape having a width that decreases as they move downwardly from each gate structure GS and an inclined side surface. The support structures 172 may be formed of an insulating material.

The second structure S2 may further include through-vias 170 and 175 penetrating through or extending into the substrate insulating layer 192 and connected to an interconnection structure 180 in a lower portion thereof and in an edge region of the second region R2. The through-vias 170 and 175 may penetrate through or extend into the cell region insulating layer 190, and may have a cylindrical shape in which a width thereof decreases as they move downwardly to have the same bent portion as the contact plugs 160. The through-vias 170 and 175 may include a conductive material, and may include the same material as the contact plugs 160, but the present disclosure is not limited thereto. The through-vias 170 and 175 may include a common voltage through-via 170 for applying voltage of the corresponding level to the horizontal conductive layer 110, respectively, and an input/output through-via 175 for receiving input/output signals, but the present disclosure is not limited thereto.

The cell region insulating layer 190 may be disposed to cover or overlap the substrate insulating layer 192 and each of the gate pad regions GP. The cell region insulating layer 190 may be formed of an insulating material and may be formed of a plurality of insulating layers.

The passivation layer 191 may be disposed on upper surfaces of the horizontal conductive layer 110 and the horizontal insulating layer 102. The passivation layer 191 may function as a layer protecting the semiconductor device 100. In some example embodiments, the passivation layer 191 has openings in some regions, and accordingly, a pad (not illustrated) connected to an external element may be formed. The passivation layer 191 may include at least one of silicon oxide, silicon nitride, and silicon carbide.

The studs 182 may form an interconnection structure 180 electrically connected to memory cells inside the memory cell region CELL. The studs 182 may be electrically connected to the first channel portions CH1 and the contact plugs 160. The studs 182 may not be disposed on support structures 172. The studs 182 are illustrated in a plug shape, but are not limited thereto and may also have a line shape. Some of the studs 182 may include upper studs 173 connected to an upper end of the contact plugs 160. In example embodiments, the number of studs 182 and interconnection lines 184, which form the interconnection structure 180, may be variously changed. The studs 182 may include a metal, for example, tungsten (W), copper (Cu), and aluminum (Al).

The cell interconnection lines 184 may include bit lines in the first region R1 connected to the channel structures CH, and interconnection lines in the second region R2 disposed on the same height level as the bit lines. The cell interconnection lines 184 may have a line shape extending in at least one direction, and may be connected to the studs 182 via plugs (not illustrated) therebetween. The cell interconnection lines 184 may include, for example, tungsten (W), aluminum (Al), copper (Cu), tungsten nitride (WN), tantalum nitride (TaN), titanium nitride (TiN), or combinations thereof.

The second bonding vias 195 of the second bonding structure may be disposed below the cell interconnection lines 184 and may be connected to the cell interconnection lines 184, and the second bonding metal layers 198 of the second bonding structure may be connected to the second bonding vias 195. A lower surface of the second bonding metal layers 198 may be exposed to a lower surface of the second structure S2. The second bonding metal layers 198 may be bonded and connected to the first bonding metal layers 298 of the first structure S1. The second bonding vias 195 and the second bonding metal layers 198 may include a conductive material, for example, copper (Cu).

In example embodiments, the substrate insulating layer 192 may include a bonding insulating layer 199 having a predetermined thickness from an upper surface thereof. In this case, the bonding insulating layer 199 may form dielectric-dielectric bonding with the bonding insulating layer 299 of the first structure S1. For example, the bonding insulating layer 199 may include at least one of SiO, SiN, SiCN, SiOC, SiON, and SiOCN.

The first and second structures S1 and S2 may be bonded by bonding the first bonding metal layers 298 and the second bonding metal layers 198 and bonding the bonding insulating layers 199 and 299. The bonding of the first bonding metal layers 298 and the second bonding metal layers 198 may be, for example, copper (Cu)-copper (Cu) bonding, and the bonding of the bonding insulating layers 199 and 299 may be, for example, dielectric-dielectric bonding, such as SiCN—SiCN bonding. The first and second structures S1 and S2 may be bonded by hybrid bonding including copper (Cu)-copper (Cu) bonding and dielectric-dielectric bonding.

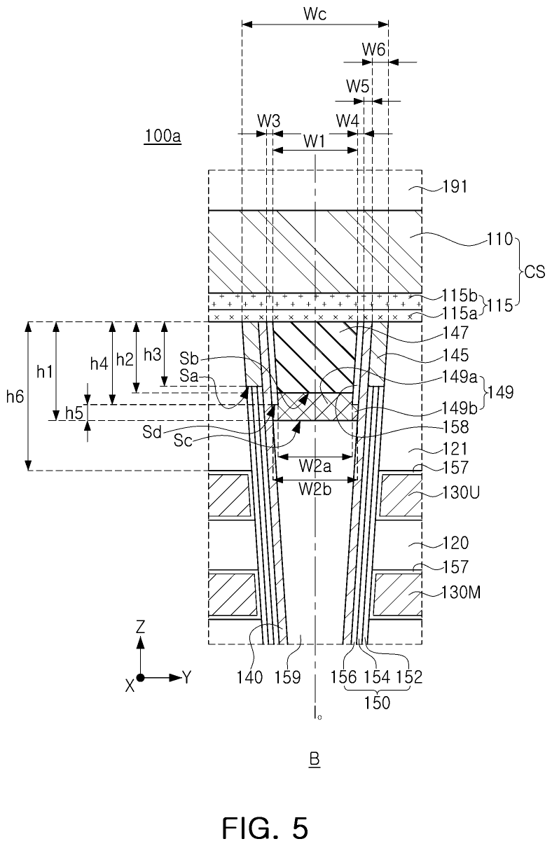

FIGS. 5 to 7 are cross-sectional views of semiconductor devices according to example embodiments. Each of FIGS. 5 to 7 illustrates enlarged views of a region corresponding to region ‘B’ in FIG. 2B.

Referring to FIG. 5, a semiconductor device 100a is the same as that illustrated in FIGS. 1 to 3, except that in the channel structures CH, lengths of the doped region 147 and the second contact layer 145 in the Z-direction are different from each other. Specifically, the doped region 147 and the second contact layer 145 may be physically and electrically spaced apart from each other by the vertical insulating layer 158. A length h2 of the doped region 147 in the Z-direction may be greater than a length h3 of the second contact layer 145 in the Z-direction. However, even when the length h2 of the doped region 147 is longer or greater, the length h2 of the doped region 147 may be shorter than a length h4 of the vertical insulating layer 158.

Accordingly, when a total length h1 of the vertical portion 149a of the first contact layer 149 is the same as FIG. 3, more impurities of a first conductivity-type may be injected so that the doped region 147 is formed to be deeper. Accordingly, holes may be transferred to the channel layer 140 more quickly during bulk erase simultaneously performed in a plurality of channel structures CH.

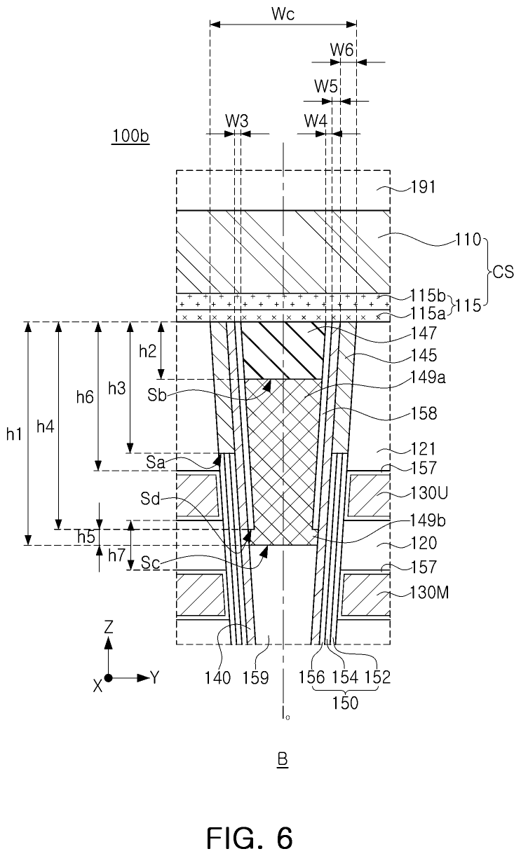

Referring to FIG. 6, a semiconductor device 100b is the same as that illustrated in FIGS. 1 to 3, except that a total length of the first contact layer 149 of the channel structures CH, that is, a length h1 of the vertical portion 149a, is formed to be relatively longer so that a level of a lower surface Sc of the first contact layer 149 is lower than a level of an upper surface of an uppermost gate electrode 130U. Specifically, a length h1 of a polycrystalline conductive layer forming the first contact layer 149 may be formed to be relatively longer and may extend from an upper end of the channel structure CH by a predetermined depth h1 in the Z-direction. This length h1 may be greater than a thickness h6 of an uppermost interlayer insulating layer 121.

Additionally, a level of the lower surface Sc of the first contact layer 149 may be lower than the level of the lower surface of the uppermost gate electrode 130U, and may be disposed in a higher position than a level of a lower surface of the interlayer insulating layer 120. In this case, a side surface of the horizontal portion 149b may be disposed in a position corresponding to the interlayer insulating layer 120, so that a level of the upper surface of the horizontal portion 149b may be lower than a level of an upper surface of the interlayer insulating layer 120. That is, the length h5 of the horizontal portion 149b may be smaller than a thickness h7 of the interlayer insulating layer 120 and may be disposed inside the thickness h7 of the interlayer insulating layer 120, and thus, the horizontal portion 149b may horizontally overlap the interlayer insulating layer 120 and may not horizontally overlap the gate electrodes 130 above and below the overlapping interlayer insulating layer. 120

When the first contact layer 149 is formed to be long, the length h4 of the vertical insulating layer 158 also increases, and the length h3 of the second contact layer 145 may be shorter than a length h1 of the first contact layer 149 and may be smaller than the thickness h6 of the uppermost interlayer insulating layer 121. In this manner, when the first contact layer 149 is formed to be long, a position in which the first contact layer 149 is in contact with the channel layer 140 and a position in which the second contact layer 145 is in contact with the channel layer 140 may become more distant, thereby minimizing mutual influence inside the channel layer 140. Additionally, since the position of the horizontal portion 149b does not overlap horizontally the gate electrode 130, an influence on the channel layer 140 in contact with the gate electrode 130, that is, a threshold voltage of a transistor, may be minimized.

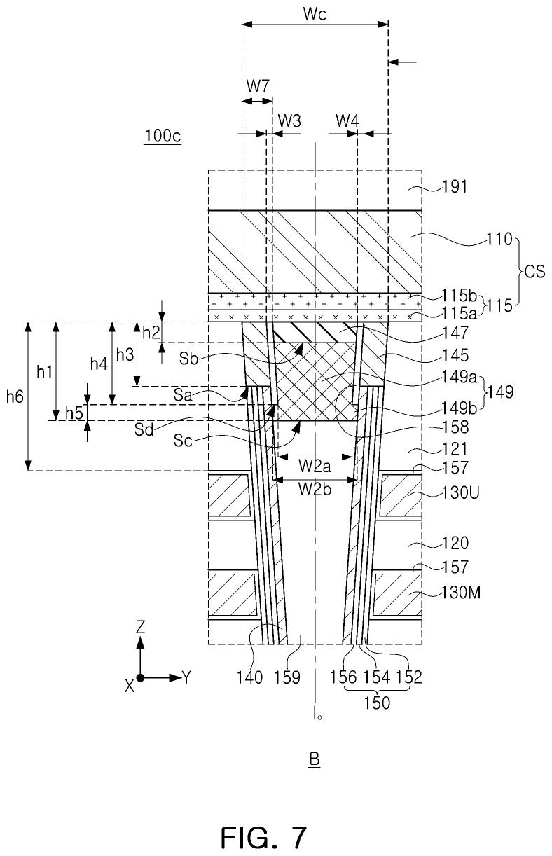

Referring to FIG. 7, a semiconductor device 100c is the same as that illustrated in FIGS. 1 to 3, except that a width W7 of the second contact layer 145 of the channel structures CH may be formed to be larger than a width of the second contact layer 145 in FIG. 3. Specifically, the structures of the first contact layer 149 and the vertical insulating layer 158 are the same as those in FIG. 3. In this case, the second contact layer 145 may be disposed on the channel dielectric layer 150 and the channel layer 140. In FIG. 7, the channel layer 140 may also be disposed on the same level as the channel dielectric layer 150, and the second contact layer 145 may be disposed on the channel layer 140. Accordingly, the second contact layer 145 may be in vertical contact with the channel layer 140 in the Z-direction and may obtain electrons from the channel layer 140 according to the common source voltage.

As the width W7 of the second contact layer 145 increases, a contact area with the horizontal conductive structure CS at the top may be secured, and as the impurity of the second conductivity-type of the second contact layer 145 diffuses into the channel layer 140, a portion of the contacted channel layer 140 may function almost like the second contact layer 145. Accordingly, operational reliability may be improved by removing an upper portion of the channel layer 140 and forming the second contact layer 145 as a whole.

In FIG. 7, lengths h2 and h3 of the doped region 147 and the second contact layer 145 are illustrated to be the same as in FIG. 3, but the present disclosure is not limited, and the features of FIG. 5 or 6 may be implemented together.

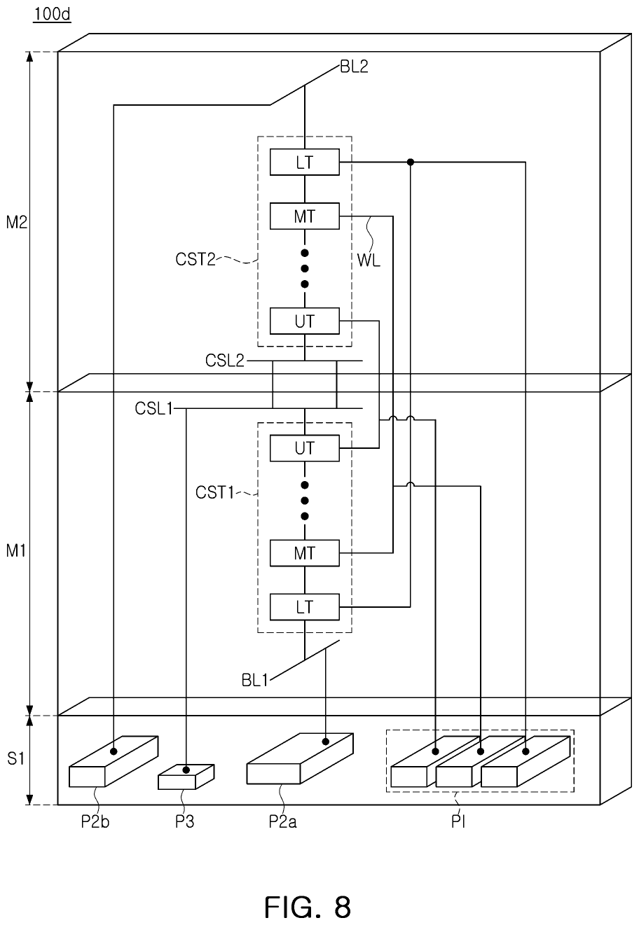

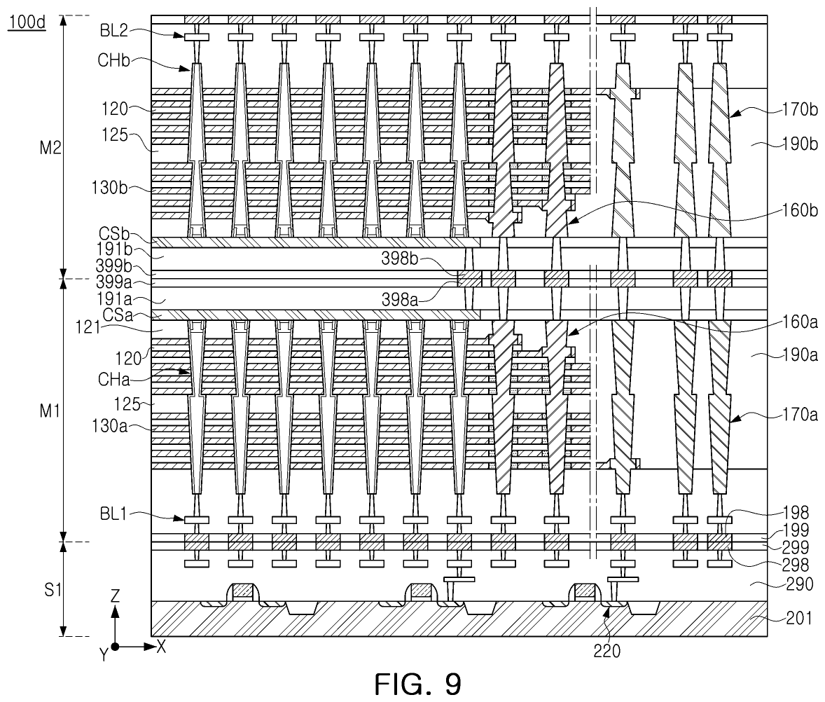

Hereinafter, a semiconductor device according to some example embodiments will be described with reference to FIGS. 8 and 9.

FIG. 8 is a view schematically illustrating a data storage system including a semiconductor device according to example embodiments, and FIG. 9 is a schematic cross-sectional view of the data storage system of FIG. 8.

Referring to FIG. 8, a semiconductor device 100d according to some example embodiments may include a first non-volatile memory structure M1 having a first memory cell array region, a second non-volatile memory structure M2 having a second memory cell array region vertically overlapping the first memory cell array region, and a peripheral circuit structure S1 electrically connected to the first non-volatile memory structure M1 and the second non-volatile memory structure M2 through connection interconnection structures. The peripheral circuit structure S1 may include a peripheral circuit PC for operating the first non-volatile memory structure M1 and the second non-volatile memory structure M2. The first non-volatile memory structure M1 and the second non-volatile memory structure M2 may be the same non-volatile memory. The peripheral circuit structure S1, the first non-volatile memory structure M1, and the second non-volatile memory structure M2 may be sequentially stacked in the vertical direction (Z-direction).

The first non-volatile memory structure M1 may include a first bit line BL1, a first lower selection line, word lines WL, a first upper selection line, a first common source line CSL1, and a first memory cell string CST1.

The first memory cell string CST1 may be disposed between the first bit line BL1 and the first common source line CSL1. The first bit line BL1 may be disposed below the first memory cell string CST1, and the first common source line CSL1 may be disposed on the first memory cell string CST1. A plurality of first memory cell strings CST1 may be disposed to form the first memory cell array region.

The first memory cell string CST1 may include a first lower selection transistor LT, first memory cell transistors MT sequentially arranged in the vertical direction (Z-direction) on the first lower selection transistor LT, and a first upper selection transistor UT on the first memory cell transistor MT. The first memory cell transistors MT may be connected in series in the vertical direction (Z-direction).

The first lower selection line may be a gate electrode of the first lower selection transistor LT. The first word lines WL may be gate electrodes of the first memory cell transistors MT. The first upper selection line may be a gate electrode of the first upper selection transistor UT. Accordingly, the first lower selection line, the first word lines WL, and the first upper selection line may be gate electrodes WL of the first memory cell string CST1.

The second non-volatile memory structure M2 may include a second bit line BL2, a second lower selection line, a second word line WL, a second upper selection line, a second common source line CSL2, and a second memory cell string CST2.

The second memory cell string CST2 may be disposed between the second bit line BL2 and the second common source line CSL2. The second bit line BL2 may be disposed on the second memory cell string CST2, and the second common source line CSL2 may be disposed below the second memory cell string CST2. A plurality of second memory cell strings CST2 may be disposed to form the second memory cell array region.

The second memory cell string CST2 may include a second lower selection transistor LT, second memory cell transistors MT sequentially arranged below the second lower selection transistor LT in the vertical direction (Z-direction), and a second upper selection transistor UT below the second memory cell transistor MT.

The second lower selection line may be a gate electrode of the second lower selection transistor LT. The second word lines WL may be gate electrodes of the second memory cell transistors MT. The second upper selection line may be a gate electrode of the second upper selection transistor UT. Accordingly, the second lower selection line, the second word lines WL, and the second upper selection line may be gate electrodes WL of the second memory cell string CST2.

The peripheral circuit structure S1 may include a first decoder circuit P1, a second decoder circuit P3, a first peripheral circuit P2a, a second peripheral circuit P2b, and a logic circuit.

The semiconductor device 100d may further include connection interconnection structures that electrically connect the first non-volatile memory structure M1 and the second non-volatile memory structure M2 to the peripheral circuit structure S1. For example, the connection interconnection structures may include a connection interconnection electrically connecting the first bit line BL1 and the first peripheral circuit P2a, and a connection interconnection electrically connecting the gate electrodes WL of the first memory cell string CST1 and the gate electrodes WL of the second memory cell string CST2 to the first decoder circuit P1. Gate electrodes of the first and second non-volatile memory structures M1 and M2 connected to the first decoder circuit P1 may be connected to each other and may receive simultaneous signals. Additionally, the connection interconnection structures may include a connection interconnection that connects the first common source line CSL1 and the second common source line CSL2 of the first and second non-volatile memory structures M1 and M2 to each other and is simultaneously connected to the second decoder circuit P3. The connection interconnection structures may also include a connection interconnection electrically connecting the second bit line BL2 and the second peripheral circuit P2b.

In some example embodiments, the first decoder circuit P1, the second decoder circuit P3, and the first peripheral circuit Pla may perform control operations on the first memory cell string CST1, the first bit line BL1, and the first common source line CSL1. The first decoder circuit P1, the second decoder circuit P3, and the second peripheral circuit P2b may perform control operations on the second memory cell string CST2, the second bit line BL2, and the second common source line CSL2. The first decoder circuit P1 and the first peripheral circuit P1b, the second decoder circuit P3, and the second peripheral circuit P2b may be controlled by the logic circuit.

In some example embodiments, the first and second non-volatile memory structures M1 and M2 arranged vertically may be included to improve a degree of integration of the semiconductor device 100d. The first and second non-volatile memory structures M1 and M2 may have the same configuration as the second structure S2 of the semiconductor device 100 illustrated in FIGS. 1 to 3.

Specifically, the semiconductor device 100d of FIG. 9 may be attached to the semiconductor device 100 of FIGS. 1 to 3 as a second non-volatile memory structure M2 by inverting the second structure S2.

Accordingly, horizontal conductive structures CSa and CSb for providing common voltage and body voltage may be disposed to face each other between the two non-volatile memory structures M1 and M2, and channel structures Cha and CHb may be disposed in opposite directions. That is, the channel pad CH_PAD of the channel structure Cha of the first non-volatile memory structure M1 and the channel pad CH_PAD of the channel structure CHb of the second non-volatile memory structure M2 may be disposed to symmetrical so that the channel pad CH_PAD and the channel pad CH_PAD face each other.

The horizontal conductive structures Csa and CSb for providing common voltage and body voltage between the two non-volatile memory structures M1 and M2 may be connected to bonding pads 398a and 398b through studs on each of the horizontal conductive structures Csa and CSb, respectively, and the bonding pads 398a and 398b may be connected to each other and may receive the common voltage or the body voltage at the same time. For this purpose, the channel structures Cha and CHb in each of the non-volatile memory structures M1 and M2 may include both a first contact layer 149 and a second contact layer 145, similarly to the channel pad CH_PAD of FIGS. 1 to 7.

Contact plugs 160a and 160b driving the respective gate electrodes 130a and 130b between the two non-volatile memory structures M1 and M2 may be connected to each other through the bonding pads 398a and 398b, and may be connected to one transistor in the first decoder circuit P1. Accordingly, a dual driving word line method in which the two gate electrodes 130a and 130b may be selected by one word line signal may be applicable. Accordingly, the number of transistors may be substantially reduced, so that it may be possible to reduce the size of the peripheral circuit region as compared to increasing memory capacitance.

The two non-volatile memory structures M1 and M2 may be bonded by metal-to-metal bonding, similarly to the bonding between the first structure S1 and the second structure S2 of FIGS. 1 to 3.

Specifically, the bonding pads 398a and 398b may be bonded to each other while coming into contact with each other through metal-to-metal bonding. For example, each of the bonding pads 398a and 398b may include a metallic material such as copper (Cu), and the bonding pads 398a and 398b may be bonded to each other while coming into contact with each other by Cu—Cu bonding. The two non-volatile memory structures M1 and M2 may be bonded to each other by bonding the bonding pads 398a and 398b and bonding insulating layers 399a and 399b. The bonding of the bonding insulating layers 399a and 399b may be, for example, dielectric-dielectric bonding, such as SiCN—SiCN bonding. In this manner, the bonding between the peripheral circuit structure S1 and the first non-volatile memory structure M1 may also be performed by hybrid bonding as illustrated in FIGS. 1 to 3, and the first and second non-volatile memory structures M1 and M2 may also be bonded by hybrid bonding including copper (Cu)-copper (Cu) bonding and dielectric-dielectric bonding.

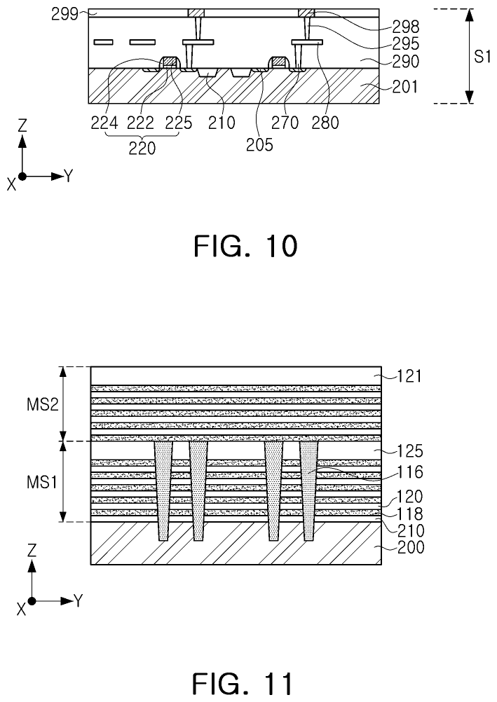

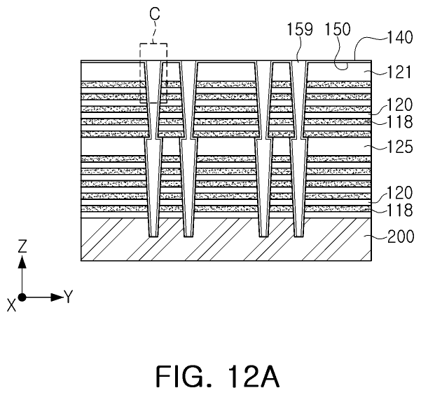

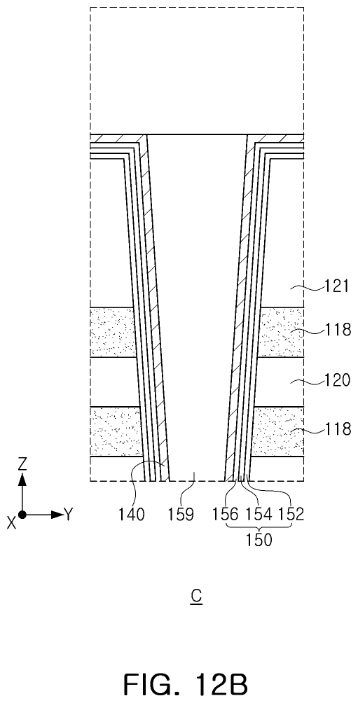

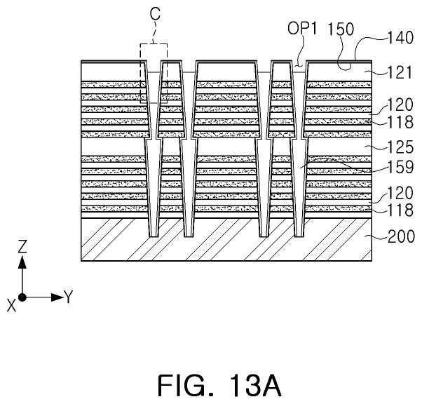

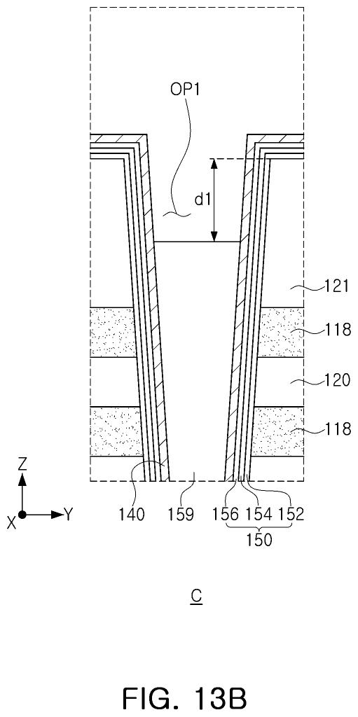

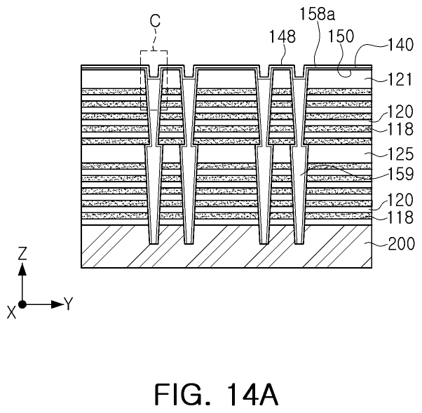

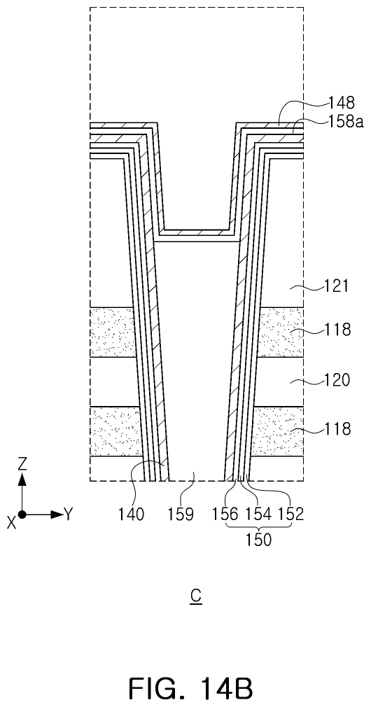

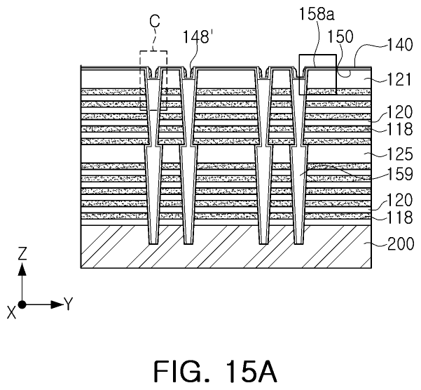

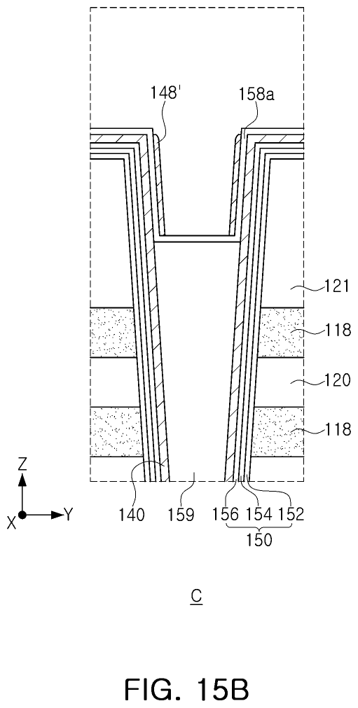

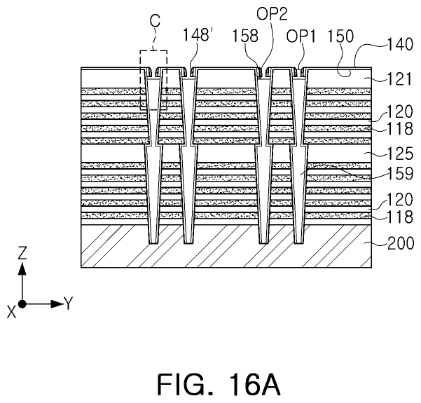

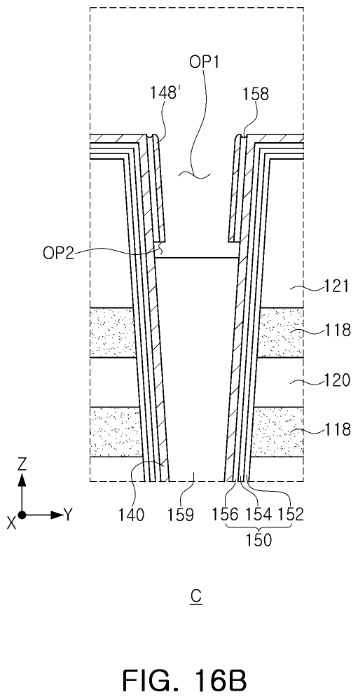

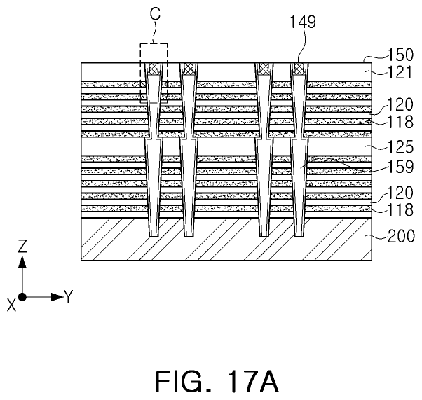

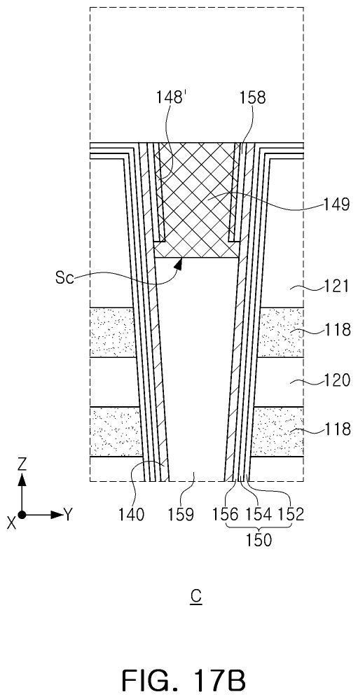

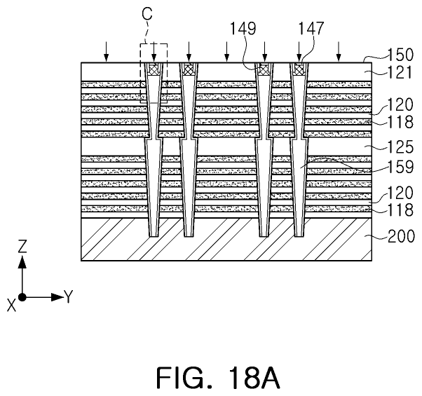

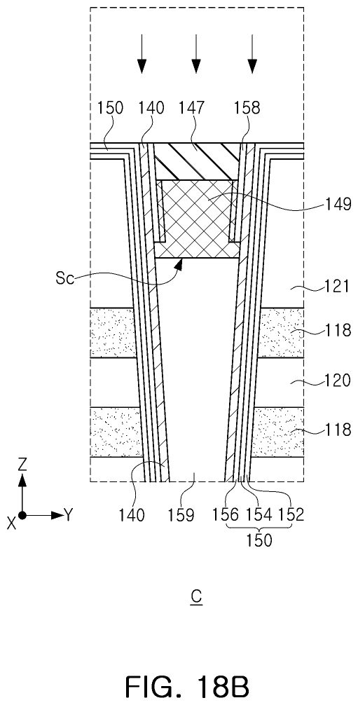

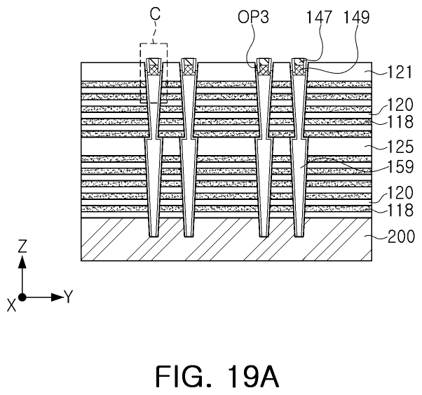

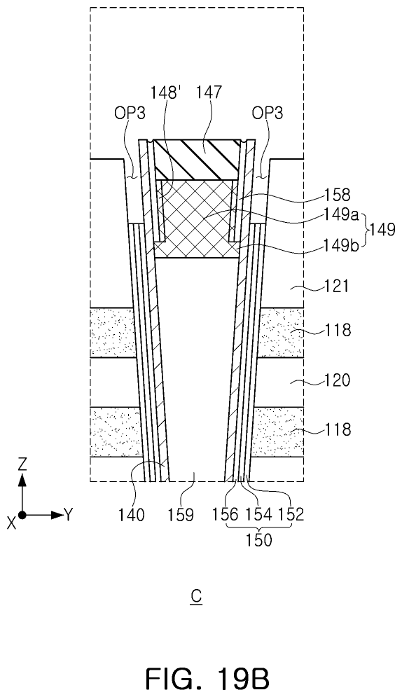

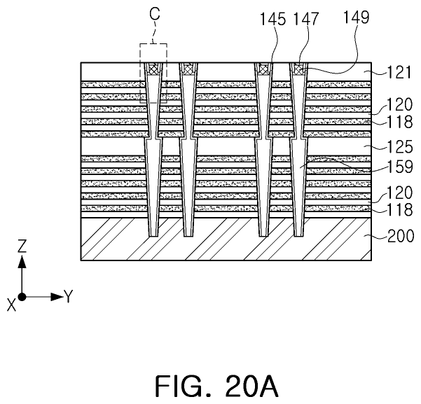

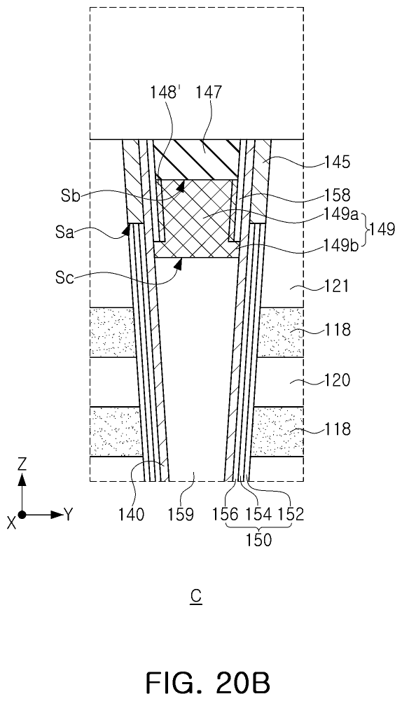

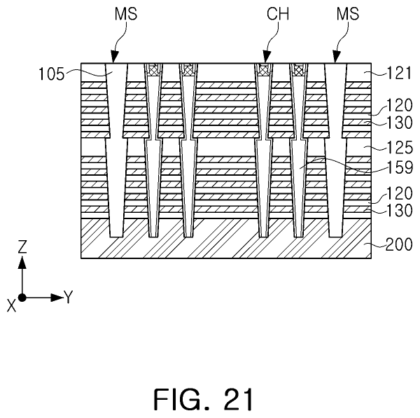

FIGS. 10 to 24 are schematic cross-sectional views illustrating a method of manufacturing a semiconductor device according to example embodiments. FIGS. 10, 11, 12A, 13A, 14A, 15A, 16A, 17A, 18A, 19A, 20A, 21, 22A, 23, and 24 illustrate regions corresponding to a region illustrated in FIG. 2B. FIGS. 12B, 13B, 14B, 15B, 16B, 17B, 18B, 19B, 20B, and 22B are enlarged views of region ‘C’ of FIGS. 12A, 13A, 14A, 15A, 16A, 17A, 18A, 19A, 20A, and 22A, respectively.

Referring to FIG. 10, a peripheral circuit region PERI including circuit elements 220 and circuit interconnection structures may be formed on a first substrate 201.

First, device isolation layers 210 may be formed in the first substrate 201, and a circuit channel dielectric layer 222 and a circuit gate electrode 225 may be sequentially formed on the first substrate 201. The device isolation layers 210 may be formed by, for example, a shallow trench isolation (STI) process. The circuit channel dielectric layer 222 and the circuit gate electrode 225 may be formed using atomic layer deposition (ALD) or chemical vapor deposition (CVD). The circuit channel dielectric layer 222 may be formed of silicon oxide, and the circuit gate electrode 225 may be formed of at least one of polycrystalline silicon or a metal silicide layer, but the present disclosure is not limited thereto. Next, a spacer layer 224 and source/drain regions 205 may be formed on both sidewalls of the circuit channel dielectric layer 222 and the circuit gate electrode 225. According to example embodiments, the spacer layer 224 may be formed of a plurality of layers. Next, an ion implantation process may be performed to form the source/drain regions 205.

Among the circuit interconnection structures, circuit contact plugs 270 may be formed by partially forming a peripheral region insulating layer 290, and then partially etching and removing the peripheral region insulating layer 290, and burying a conductive material therein. Circuit interconnection lines 280 may be formed, for example, by depositing a conductive material and then patterning the conductive material.

The peripheral region insulating layer 290 may be formed of a plurality of insulating layers. The peripheral region insulating layer 290 may be formed so that a portion thereof is formed in each operation of forming the circuit interconnection structures and a portion thereof is formed on an upper portion of an uppermost circuit interconnection line 280, thereby finally covering or overlapping the circuit elements 220 and the circuit interconnection structures.

Referring to FIG. 11, on a sacrificial substrate 200, a mold structure MS provided with a memory cell region may be formed, and sacrificial vertical structures may be formed.

The sacrificial substrate 200 is a substrate that is removed during formation of a second structure S2 and may be, for example, a silicon substrate. A sacrificial substrate insulating layer 210 may be further formed on the sacrificial substrate 200, but the present disclosure is not limited thereto. The sacrificial substrate insulating layer 210 may be a partial oxide layer of the sacrificial substrate 200, but the present disclosure is not limited thereto.

A plurality of sacrificial vertical structures may be formed on the sacrificial substrate insulating layer 210. A first mold structure MS1 of the mold structure MS may be formed on the sacrificial substrate 200, and the sacrificial vertical structures including channel sacrificial layers 116 penetrating through or extending into the first mold structure MS1 and vertical sacrificial layers (not illustrated) in a region in which contact plugs and through-vias are formed may be formed. The first mold structure MS1 may be formed on the sacrificial substrate 200 at a height at which the first gate structure GS1 (see FIG. 2B) is disposed. The sacrificial insulating layers 118 may be a layer in which at least a portion of the sacrificial insulating layers 118 are replaced with some of the gate electrodes 130 (see FIG. 2B) in a subsequent process. The sacrificial insulating layers 118 may be formed of a material different from the interlayer insulating layers 120, and may be formed of a material that may be etched with etch selectivity under specific etching conditions for the interlayer insulating layers 120. For example, the interlayer insulating layer 120 may be formed of at least one of silicon oxide and silicon nitride, and the sacrificial insulating layers 118 may be formed of a material different from the interlayer insulating layer 120 selected from silicon, silicon oxide, silicon carbide, and silicon nitride. The number of interlayer insulating layers 120 and sacrificial insulating layers 118 may be changed variously from those shown. A gate pad region GP may be formed by repeatedly performing a photolithography process and an etching process on the sacrificial insulating layers 118 and the interlayer insulating layers 120.

Channel sacrificial layers 116 may be formed in areas corresponding to the first channel structures CH1 of FIG. 2B. The channel sacrificial layers 116 may be formed by forming lower channel holes to penetrate through or extend into the first mold structure MS1, and then, depositing a material forming the channel sacrificial layers 116 on the lower channel holes and forming a flattening process. The channel sacrificial layers 116 may include a material different from the interlayer insulating layers 120 and the sacrificial insulating layers 118. For example, the channel sacrificial layers 116 may include a semiconductor material such as polycrystalline silicon, a silicon-based insulating material, or a carbon-based material. Next, an uppermost interlayer insulating layer 121 covering or overlapping the mold structures MS1 and MS2 of the sacrificial insulating layers 118 and the interlayer insulating layers 120 may be formed.

Referring to FIGS. 12A and 12B, channel holes CHH may be formed that penetrate through or extend into the first and second mold structures MS1 and MS2, and channel dielectric layers 150 and channel layers 140 may be formed within the channel holes CHH.

The channel holes CHH may be formed by anisotropically etching the first and second mold structures MS1 and MS2 using a mask layer. Due to a height of the stacked mold structures MS1 and MS2, sidewalls of the channel holes CHH may not be perpendicular to an upper surface of the sacrificial substrate 200. The channel holes CHH may be formed to recess a portion of the sacrificial substrate 200.

The channel dielectric layers 150 may be formed by sequentially depositing a blocking layer 152, a charge storage layer 154, and a tunneling layer 156 in the channel holes CHH. The channel dielectric layers 150 may be formed to have a uniform thickness using an atomic layer deposition (ALD) or chemical vapor deposition (CVD) process.

A channel layer 140 may be formed on the channel dielectric layer 150 inside the channel holes. In this case, the formed channel dielectric layer 150 and channel layer 140 may be formed to extend above an upper surface of the uppermost interlayer insulating layer 121. The channel buried insulating layer 159 may be formed to fill the channel holes CHH, and by etching the channel buried insulating layer 159 until the channel layer 140 is exposed to an upper portion of the uppermost interlayer insulating layer 121 by chemical mechanical polishing (CMP), the channel buried insulating layer 159 may remain only inside the channel holes CHH. The channel buried insulating layer 159 may be an insulating material.

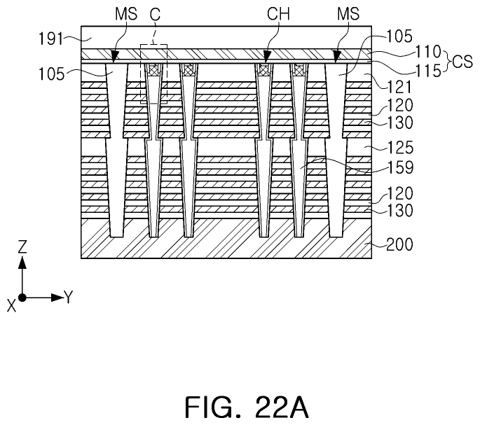

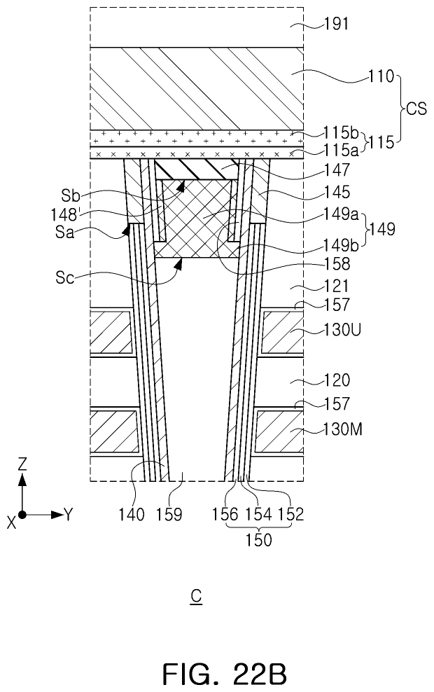

Referring to FIGS. 13A and 13B, the channel buried insulating layers 159 may be etched inside the channel holes CHH to form a first opening OP1 in which a channel pad CH_PAD is to be formed.

The channel buried insulating layers 159 inside the channel holes CHH may be removed from a level of the upper surface of the uppermost interlayer insulating layer 121 to a predetermined depth d1. Accordingly, a space may be formed in an upper end of the channel buried insulating layers 159 inside each channel hole CHH, and the predetermined depth d1 may be smaller than the length h1 of the first contact layer 149.

Referring to FIGS. 14A and 14B, an insulating layer 158a and a sacrificial semiconductor layer 148 may be formed along a side surface and a bottom surface of the first opening OP1 in the upper end of the channel hole CHH on the channel buried insulating layers 159.

The insulating layer 158a and the sacrificial semiconductor layer 148 may be formed on the channel layers 140 and the channel buried insulating layers 159 inside the channel holes CHH, and may extend outside the channel holes CHH and be stacked on the channel layers 140 even on the uppermost interlayer insulating layer 121. In this operation, the insulating layer 158a may include silicon oxide, and the sacrificial semiconductor layer 148 may be formed of a semiconductor material such as amorphous silicon.

In this case, a thickness of the sacrificial semiconductor layer 148 may be equal to or greater than a thickness of the insulating layer 158a, and the insulating layer 158a and the sacrificial semiconductor layer 148 may be deposited to conformally cover or overlap the channel layers 140 and the channel buried insulating layers 159. Accordingly, the insulating layer 158a inside the channel holes CHH may have a predetermined thickness W4. The thickness W4 of the insulating layer 158a may be smaller than a thickness W5 of the channel layer 140.

Referring to FIGS. 15A and 15B, a portion of the sacrificial semiconductor layer 148 may be removed to expose a portion of the channel buried insulating layer 159.

An operation of removing a portion of the sacrificial semiconductor layer 148 may be achieved by selectively removing only the sacrificial semiconductor layer 148 vertically through post-etching or dry etching, and exposing an upper surface of the channel buried insulating layer 159 inside the channel holes CHH. Due to such dry etching, a portion of the insulating layer 148a on the upper surface of the channel buried insulating layer 159 may remain, and may be recognized as the channel buried insulating layer 159 by including the same material as the channel buried insulating layer 159. Accordingly, the sacrificial semiconductor layer 148 may remain only on a side surface of the channel hole CHH on the channel buried insulating layer 159 and may function as a side spacer 148′ on the insulating layer 148a.

Referring to FIGS. 16A and 16B, wet etching may be performed on the channel structures CH to remove a portion of the exposed channel buried insulating layer 159 to form a second opening OP2.

The second opening OP2 may be expanded from the first opening OP1 to an upper portion thereof and a side surface below the spacer 148′ by isotropy of wet etching, and may partially expose an inner surface of the channel layer 140 below the insulating layer 158a. Accordingly, a space in which the first contact layer 149 is to be formed may be formed by the first opening OP1 and the second opening OP2. By such wet etching, the insulating layer 158a on the uppermost interlayer insulating layer 121 may also be removed, and the channel layer 140 at the bottom may be exposed. Accordingly, the insulating layer 158a may remain only on a side surface of the upper end of the channel holes CHH to form the vertical insulating layer 158. In this case, a portion of the vertical insulating layer 158 remaining in the channel holes CHH in the upper end of the channel holes CHH may also be etched to form a concave groove, but the groove may not be formed deeply due to a thin width W4 of the vertical insulating layer 158, and thus, a lower surface of the groove may be disposed on a level higher than a level of the upper surface of the uppermost interlayer insulating layer 121.

Referring to FIGS. 17A and 17B, a first contact layer 149 may be formed by filling the first opening OP1 and the second opening OP2.

The first contact layer 149 may be formed by filling a space on the channel buried insulating layer 159 in the upper end of the channel holes CHH and depositing a conductive material on the channel layer 140. The first contact layer 149 may be formed of a conductive material, and may include a conductive semiconductor layer, and may have a different crystal quality from the channel layer 140. For example, the first contact layer 149 may be formed of polysilicon. Next, an etch-back or chemical mechanical polishing (CMP) process may be performed from polysilicon until an upper surface of the channel dielectric layer 150 is exposed, so that as illustrated in FIG. 16B, the first contact layer 149 and the channel dielectric layer 150 May be coplanar with each other, and the first contact layer 149 may be etched to be formed such that it is in the channel hole CHH. Through such etching, the channel layer 140 on the uppermost interlayer insulating layer 121 may also be removed, so that the channel dielectric layer 150 at the bottom may be exposed on an upper surface thereof.

Referring to FIGS. 18A and 18B, a doped region 147 may be formed in the first contact layer 149. An operation of forming the doped region 147 may be achieved by injecting a high concentration of an impurity of a first conductive type, for example, a P-type impurity, into the channel structures CH and activating the impurity by heat treatment, and then forming the doped region 147 having a first conductivity-type from the upper surface of the first contact layer 149 to a predetermined depth h2. In this case, regions other than the upper surface of the first contact layer 149, which are covered/overlapped and doped with the channel dielectric layer 150, may be limited to upper portions of the first contact layer 149 and the channel layer 140. Accordingly, doping may be selectively performed only in specific regions without an additional mask.

Referring to FIGS. 19A and 19B, a third opening OP3 may be formed by removing the channel dielectric layer 150 from the upper surface of the channel structures CHH to a predetermined depth h3.

A process of forming the third opening OP3 may be performed in multiple operations, and first, wet etching may be performed to remove the tunneling layer 156. Accordingly, the tunneling layer 156, which is an uppermost oxide film, may be removed to expose the charge storage layer 154 at the bottom. Next, wet etching may be performed to selectively remove the charge storage layer 154, which is a nitride film. The blocking layer 152 at the bottom may be exposed by the etching. Next, wet etching may be performed to selectively etch the blocking layer 152, which is an oxide film. An upper surface of the uppermost interlayer insulating layer 121 may exposed by a plurality of etching using different etchants, and the third opening OP3 having a predetermined depth h3 from the upper surface of the uppermost interlayer insulating layer 121 may be formed in the channel dielectric layer 150. In this case, the channel structures CH may be blocked by the channel layer 140 and the channel pad CH_PAD, thus preventing or inhibiting damage in a plurality of etching processes without a separate mask.

An upper end of the vertical insulating layer 158 of the channel structures CH may be partially depressed due to multi-stage etching, but a depression depth may be disposed above a level of the upper surface of the uppermost interlayer insulating layer 121 and may be subsequently removed.

Referring to FIGS. 20A and 20B, a second contact layer 145 may be formed by filling the third opening OP3.

An operation of forming the second contact layer 145 may be achieved in a manner in that a silicon source gas and a doping source gas including an impurity of a second conductivity-type may be co-flowed and deposited. For example, the silicon source gas may include at least one of monosilane (SiH₄), disilane (Si₂H₆), trisilane (Si₃H₈), and dichlorosilane (SiH₂Cl₂). After such deposition, the impurity of the second conductivity-type may be activated through heat treatment, so that the second contact layer 145 may have a second conductivity-type, for example, an N-type conductivity-type. Next, a chemical mechanical polishing (CMP) process may be performed from polysilicon until the upper surface of the uppermost interlayer insulating layer 121 is exposed, so that as illustrated in FIG. 20B, the second contact layer 145, the first contact layer 149, the channel layer 140, and the vertical insulating layer 158 may be formed to be in the channel hole CHH and to be all coplanar with the upper surface of the uppermost interlayer insulating layer 121 The channel pad CH_PAD formed in this manner may be formed to have a structure in which the doped region 147 of the first contact layer 149 is formed with a first conductivity-type in a central region of an upper surface of the channel structure CH, the second contact layer 145 is formed to at least partially surround the doped region 147 with a second conductivity-type, and a vertical insulating layer 158 is disposed between the first contact layer 149 and the second contact layer 145. In this way, the vertical insulating layer 158 may be disposed between the first contact layer 149 and the second contact layer 145, and thus, during heat treatment to activate the second contact layer 145, diffusion of the impurity of the second conductivity-type into the first contact layer 149 may be prevented or inhibited.

As illustrated in FIG. 21, openings penetrating through or extending into the first and second mold structures MS1 and MS2 may be formed, and the sacrificial insulating layers 118 may be removed. The sacrificial insulating layers 118 may be removed selectively with respect to the interlayer insulating layers 120 using, for example, wet etching. Accordingly, a plurality of tunnel portions may be formed between the interlayer insulating layers 120. Gate electrodes 130 may be formed by filling the tunnel portions with a conductive material, and a gate separation insulating layer 105 may be formed.

The conductive material forming the gate electrodes 130 may fill or be in the tunnel portions. The conductive material may include a metal, polycrystalline silicon, or metal silicide material. After forming the gate electrodes 130, the conductive material deposited in the openings may be removed in an additional process to form the gate separation insulating layer 105.

Referring to FIGS. 22A and 22B, a horizontal conductive structure CS may be formed on upper surfaces of the channel structures CH and the uppermost interlayer insulating layer 121.

A horizontal contact layer 115a may be formed, and a metal barrier 115b may be formed on the horizontal contact layer 115a. A horizontal conductive structure CS may be formed by forming the horizontal conductive layer 110 on the metal barrier 115b. For example, the horizontal conductive layer 110 may be formed of a metal such as tungsten using a chemical physical vapor deposition method. A horizontal insulating layer 102 may be further formed on the second region R2 on a level corresponding to the horizontal conductive structure CS, and a passivation layer 191 may be formed to cover or overlap both the horizontal conductive structure CS and the horizontal insulating layer 102.

Referring to FIG. 23, in a state in which the horizontal conductive structure CS is formed, the gate structure GS may be transferred to a carrier substrate 300, and a sacrificial substrate 200 at the bottom may be turned over to be exposed to the top. Specifically, when the gate structure GS is turned over so that the passivation layer 191 is in contact with the carrier substrate 300, the channel structures CH and the insulating regions MS may be disposed in an opposite direction so that widths thereof increase as the channel structures CH and the insulating regions MS move downwardly below the sacrificial substrate 200 and the sacrificial substrate insulating layer 210 exposed to the top.

A lower insulating region SS penetrating through or extending into a lower gate electrode layer 130L exposed to the top may be formed. Specifically, the sacrificial substrate 200 exposed to the top may be removed by etching. When removing the sacrificial substrate 200, the sacrificial substrate 200 may be removed up to the sacrificial substrate insulating layer 210, but may remain and function as a lower interlayer insulating layer. A lower insulating region SS may be formed to separate at least one lower gate electrode 130L from an exposed lower surface of the gate structure GS.

The lower insulating region SS may be formed in a space in which the first channel portions CH1 are spaced apart from each other, and may be formed by forming an opening by performing etching to separate at least one lower gate electrode 130L and then filling the opening with the separation insulating material 103.

The opening forming the lower insulating region SS may be etched from a lower surface exposed to the top, so that a width is largest on the lower surface and may be reduced towards the top, and may have a slope in a direction opposite to a slope direction of the first channel portion CH1. Accordingly, a process margin may be secured by arranging a lower surface having the largest width of the lower insulating region SS between lower surfaces having the smallest width of the first channel portion CH1, and the lower insulating region SS may be formed without damaging the first channel portion CH1. In this case, a channel dielectric layer 150 may be opened on a portion of the lower surface of the first channel portion CH1 of the channel structure CH, and the exposed channel layer 140 may be doped with impurities, thus further forming a lower channel pad. Doping of the impurities may be performed by forming the substrate insulating layer 192 on the exposed gate structure GS, and then forming an opening for opening an end of the first channel portion CH1 of the channel structures CH, and removing the channel dielectric layer 150 through the opening. Interconnection structures 180 and second bonding structures 195, 198 and 199 may be formed on the lower surface of the gate structure GS.

In cell interconnection structures 180, the substrate insulating layer 192 may be etched on the lower channel pads, the contact plugs 160, and the through-vias 170 and 175, and a conductive material may be deposited and patterned, thus forming studs 182 and cell interconnection lines 184 connected to the studs 182.

Second bonding vias 195 and second bonding metal layers 198 forming the second bonding structures 195, 198 and 199 may be formed by further forming the bonding insulating layer 199 on the cell interconnection structures 180 and then partially removing the bonding insulating layer 199. An upper surface of the second bonding metal layers 198 may be exposed from the bonding insulating layer 199.

Referring to FIG. 24, the first structure S1 and the second structure S2 may be bonded.

The first structure S1 and the second structure S2 may be connected by bonding first bonding metals 298 and second bonding metal layers 198 by applying pressure. At the same time, the bonding insulating layers that are part of the peripheral region insulating layer 290 and the cell region insulating layer 190 may also be bonded by applying pressure. Specifically, the second structure S2 may be turned over again on the first structure S1 so that the second bonding metal layers 198 face downward, and then, bonding may be performed. In the drawings, for aiding understanding, the second structure S2 is illustrated as being bonded in a form that is a mirror image of a structure illustrated in FIG. 23.

The first structure S1 and the second structure S2 may be directly bonded without the intervention of an adhesive such as a separate adhesive layer. According to example embodiments, before bonding, to strengthen bonding force, a surface treatment process such as a hydrogen plasma treatment may be further performed on an upper surface of the first structure S1 and a lower surface of the second structure S2.

On a bonding structure of the first and second structures S1 and S2, the carrier substrate 300 of the second structure S2 may be removed to expose the passivation layer 191. A pad structure connected to the outside may be further formed on the passivation layer 191. The pad structure may include a through-via for connection to a lower structure of the passivation layer 191 and a pad structure on the passivation layer 191, thereby manufacturing the semiconductor device 100.

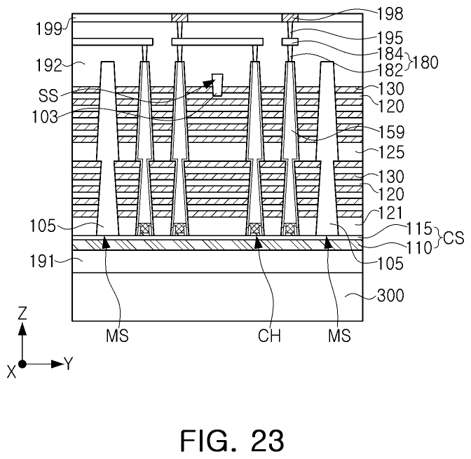

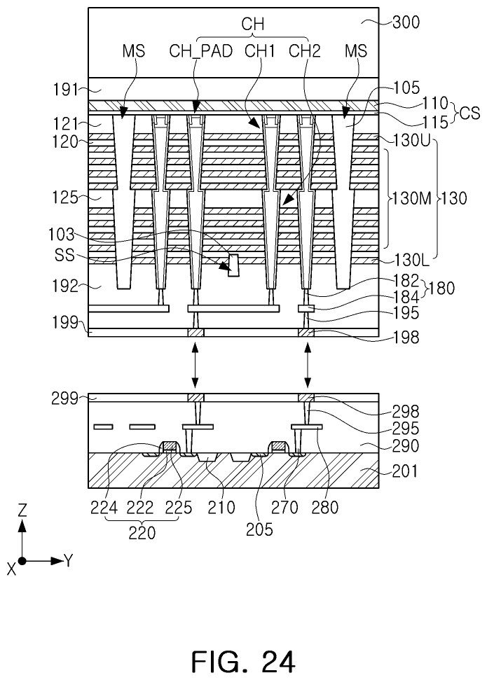

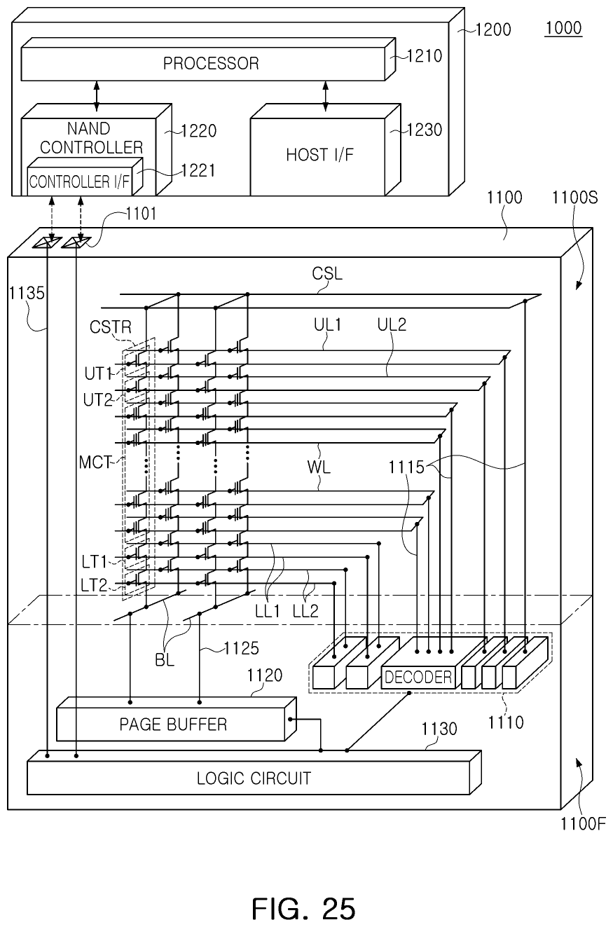

FIG. 25 is a view schematically illustrating a data storage system including a semiconductor device according to example embodiments.

Referring to FIG. 25, a data storage system 1000 may include a semiconductor device 1100 and a controller 1200 electrically connected to the semiconductor device 1100. The data storage system 1000 may be a storage device including one or a plurality of semiconductor devices 1100 or an electronic device including a storage device. For example, the data storage system 1000 may be a solid state drive device (SSD), a universal serial bus (USB), a computing system, a medical device, or a communication device, including one or a plurality of semiconductor devices 1100.

The semiconductor device 1100 may be a non-volatile memory device, for example, the NAND flash memory device described above with reference to FIGS. 1 to 7. The semiconductor device 1100 may include a first structure 1100F and a second structure 1100S on the first structure 1100F. In example embodiments, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell string CSTR may include upper transistors UT1 and UT2 adjacent to the common source line CSL, lower transistors LT1 and LT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be changed variously depending on example embodiments.

In example embodiments, the upper transistors UT1 and UT2 may include a ground select transistor, and the lower transistors LT1 and LT2 may include string selection transistors. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

In example embodiments, the upper transistors UT1 and UT2 may include a lower erase control transistor UT1 and a ground selection transistor UT2 connected in series. The lower transistors LT1 and LT2 may be string select transistors LT1 and LT2 connected in series.

The common source line CSL, the first and second gate lower lines LL1 and LL2, the word lines WL, and the first and second gate upper lines UL1 and UL2 may be electrically connected to the decoder circuit 1110 through first connection interconnections 1115 extending from the first structure 1100F to the second structure 1100S. The bit lines BL may be electrically connected to the page buffer 1120 through second connection interconnections 1125 extending from the first structure 1100F to the second structure 1100S.

In the first structure 1100F, the decoder circuit 1110 and the page buffer 1120 may perform a control operation on at least one selection memory cell transistor, among a plurality of memory cell transistors MCT. The decoder circuit 1110 and page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection interconnection 1135 extending from the first structure 1100F to the second structure 1100S.

The controller 1200 may include a processor 1210, a NAND controller 1220, and a host interface 1230. According to example embodiments, the data storage system 1000 may include a plurality of semiconductor devices 1100, and in this case, the controller 1200 may control the plurality of semiconductor devices 1100.

The processor 1210 may control an overall operation of the data storage system 1000, including the controller 1200. The processor 1210 may operate according to predetermined firmware, and may control the NAND controller 1220 to access the semiconductor device 1100. The NAND controller 1220 may include a controller interface 1221 processing communication with the semiconductor device 1100. Through the controller interface 1221, control commands for controlling the semiconductor device 1100, data to be recorded in the memory cell transistors MCT of the semiconductor device 1100, and data to be read from the memory cell transistors MCT of the semiconductor device 1100 may be transmitted. The host interface 1230 may provide a communication function between the data storage system 1000 and an external host. When receiving a control command from an external host through the host interface 1230, the processor 1210 may control the semiconductor device 1100 in response to the control command.

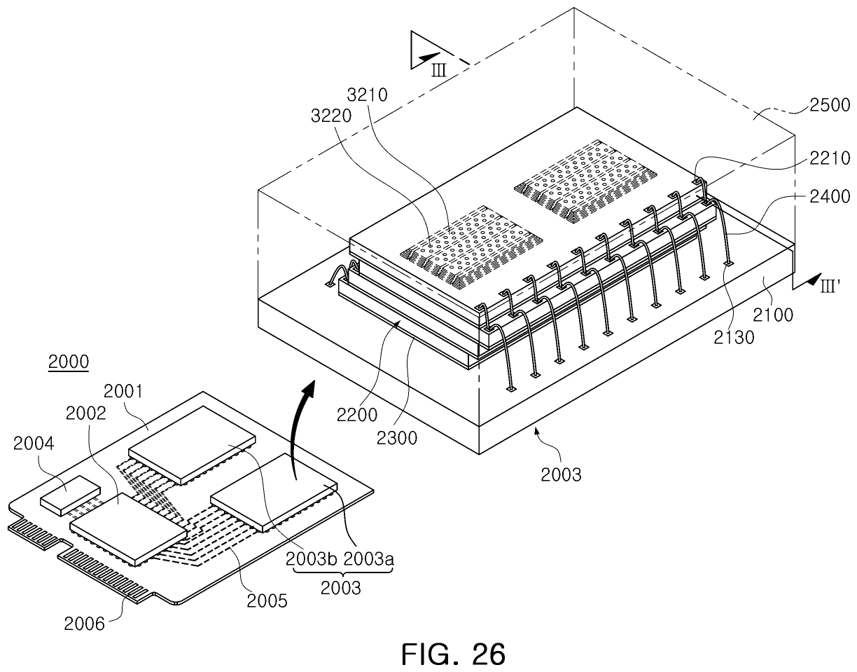

FIG. 26 is a perspective view schematically illustrating a data storage system including a semiconductor device according to an embodiment.

Referring to FIG. 26, a data storage system 2000 according to some example embodiments of the present disclosure may include a main board 2001, a controller 2002 mounted on the main board 2001, one or more semiconductor packages 2003, and a DRAM 2004. A semiconductor package 2003 and the DRAM 2004 may be connected to the controller 2002 through interconnection patterns 2005 formed on the main board 2001.

The main board 2001 may include a connector 2006 including a plurality of pins coupled to an external host. The number and arrangement of the plurality of pins in the connector 2006 may vary, depending on the communication interface between the data storage system 2000 and the external host. In example embodiments, the data storage system 2000 may communicate with an external host according to any one of the interfaces, such as Universal Serial Bus (USB), Peripheral Component Interconnect Express (PCI-Express), Serial Advanced Technology Attachment (SATA), and M-Phy for Universal Flash Storage (UFS). In example embodiments, the data storage system 2000 may operate with power supplied from the external host through the connector 2006. The data storage system 2000 may further include a power management integrated circuit (PMIC) distributing power supplied from the external host to the controller 2002 and the semiconductor package 2003.

The controller 2002 may record data in the semiconductor package 2003 or read data from the semiconductor package 2003, and may improve operating speed of data storage system 2000.

The DRAM 2004 may be a buffer memory for alleviating a speed difference between the semiconductor package 2003, which is a data storage space, and the external host. The DRAM 2004 included in the data storage system 2000 may also operate as a type of cache memory, and may provide a space for temporarily storing data during control operations for the semiconductor package 2003. When the data storage system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may include a plurality of semiconductor chips 2200. Each of the first and second semiconductor packages 2003a and 2003b may include a package substrate 2100, a semiconductor chips 2200 on the package substrate 2100, adhesive layers 2300 disposed on lower surfaces of each of the semiconductor chips 2200, a connection structure 2400 electrically connecting the semiconductor chips 2200 and the package substrate 2100, and a molding layer 2500 covering or overlapping the semiconductor chips 2200 and the connection structure 2400 on the package substrate 2100.

The package substrate 2100 may be a printed circuit board including package upper pads 2130. Each of the semiconductor chips 2200 may include an input/output pad 2210. The input/output pad 2210 may correspond to the input/output pad 1101 of FIG. 8. Each of the semiconductor chips 2200 may include gate structures 3210 and channel structures 3220. Each of the semiconductor chips 2200 may include the semiconductor device described above with reference to FIGS. 1 to 7.

In example embodiments, the connection structure 2400 may be a bonding wire electrically connecting the input/output pad 2210 and the package upper pads 2130. Accordingly, in each of the first and second semiconductor packages 2003a and 2003b, the semiconductor chips 2200 may be electrically connected to each other using a bonding wire manner, and may be electrically connected to the package upper pads 2130 of the package substrate 2100. According to example embodiments, in each of the first and second semiconductor packages 2003a and 2003b, instead of the connection structure 2400 of the bonding wire manner, the semiconductor chips 2200 may be electrically connected to each other by a connection structure including a through-silicon via (TSV).

In example embodiments, the controller 2002 and semiconductor chips 2200 may be included in a single package. In some example embodiments, the controller 2002 and the semiconductor chips 2200 may be mounted on a separate interposer board different from the main board 2001, and the controller 2002 and the semiconductor chips 2200 may be connected to each other through an interconnection formed on the interposer substrate.

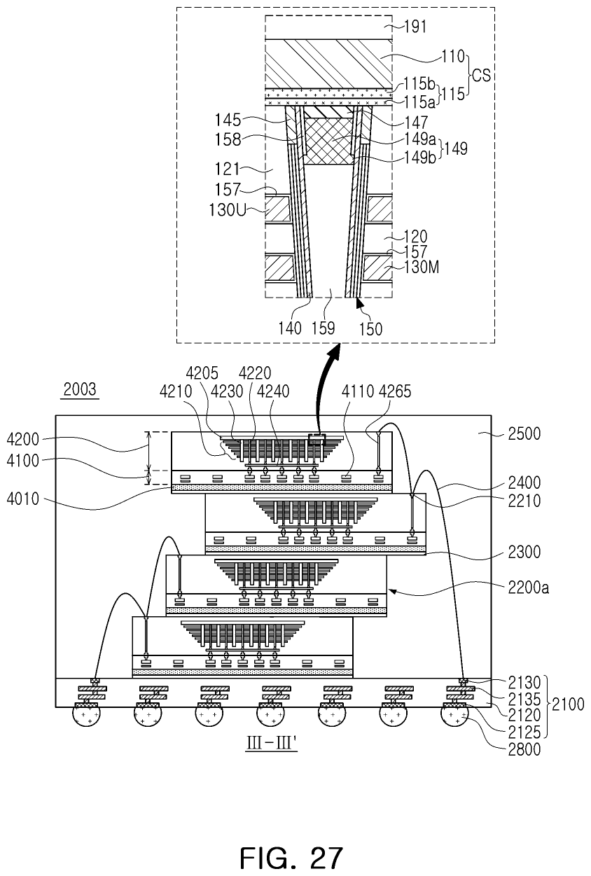

FIG. 27 is a cross-sectional view schematically illustrating a semiconductor package according to some example embodiments. FIG. 27 illustrates some example embodiments of the semiconductor package 2003 of FIG. 26, and conceptually represents a region in which the semiconductor package 2003 of FIG. 26 is cut along the cutting line III-III′.

Referring to FIG. 27, in the semiconductor package 2003, the package substrate 2100 may be a printed circuit board. The package substrate 2100 may include a package substrate body portion 2120, package upper pads 2130 (see FIG. 26) disposed on an upper surface of the package substrate body portion 2120, upper pads 2125 disposed on or exposed through the upper surface of the package substrate body 2120, and internal interconnections 2135 electrically connecting the upper pads 2130 and the lower pads 2125 inside the package substrate body portion 2120. The lower pads 2125 may be connected to the interconnection patterns 2005 of the main board 2001 of the data storage system 2000 as illustrated in FIG. 26 through conductive connection portions 2800.

Each of the semiconductor chips 2200 may include a semiconductor substrate 4010 and a first structure 4100 and a second structure 4200 sequentially stacked on a semiconductor substrate 4010. The first structure 4100 may include a peripheral circuit region including peripheral interconnections 4110. The second structure 4200 may include a common source line 4205, a gate structure 4210 on the common source line 4205, channel structures 4220 penetrating through or extending into the gate structure 4210, bit lines 4240 electrically connected to the channel structures 4220, and contact plugs 4230 electrically connected to the word lines WL (see FIG. 26) of the gate structure 4210. As described above with reference to FIGS. 1 to 7, each of the semiconductor chips 2200 may include both a first contact layer 149 of a first conductivity-type and a second contact layer 145 of a second conductivity-type that are in direct contact with the horizontal conductive structure CS on the channel structures CH. Accordingly, common source voltage may be applied by selectively electrically connecting the channel layer 140 and the horizontal conductive structure CS according to a voltage level applied according to driving, or bulk erase may be performed by injecting holes into the channel layer 140.

Each of the semiconductor chips 2200 may include a through-interconnection 4265 electrically connected to the peripheral interconnections 4110 of the first structure 4100 and extending into the second structure 4200. The through-interconnection 4265 may be disposed outside the gate structure 4210 and may be further disposed to penetrate through or extend into the gate structure 4210. Each of the semiconductor chips 2200 may further include an input/output pad 2210 (see FIG. 26) electrically connected to the peripheral interconnections 4110 of the first structure 4100.

Although the embodiments of the present disclosure have been described with reference to the accompanying drawings, the present disclosure is not limited to the above embodiments and may be implemented in various different forms. Those of ordinary skill in the technical field to which the present disclosure belongs will be able to understand that the present disclosure may be implemented in other specific forms without changing the technical idea or essential characteristics of the present disclosure. Therefore, it should be understood that the embodiments as described above are not restrictive but illustrative in all respects.

What is claimed is:

1. A semiconductor device, comprising:
a stack structure that comprises gate electrodes spaced apart from each other in a first direction, wherein the stack structure defines a channel hole that extends in the first direction, wherein a width of an upper end of the channel hole in a second direction is greater than a width of a lower end of the channel hole in the second direction, and wherein the second direction is perpendicular to the first direction;
a conductive structure on the stack structure; and
a channel structure in the channel hole,
wherein the channel structure comprises:
a channel dielectric layer on an inner surface of the channel hole;
a channel layer that is on the channel dielectric layer, is in the channel hole, and extends from the upper end of the channel hole to the lower end of the channel hole;
a first contact layer that contacts an inner surface of the channel layer and extends from the upper end of the channel hole in the first direction, wherein the first contact layer comprises an impurity of a first conductivity-type; and
a second contact layer that contacts an outer surface of the channel layer and extends from the upper end of the channel hole in the first direction, wherein the second contact layer comprises an impurity of a second conductivity-type different from the first conductivity-type, and
wherein each of an upper surface of the first contact layer and an upper surface of the second contact layer contacts a lower surface of the conductive structure.

2. The semiconductor device of claim 1, wherein the first contact layer further comprises:
a vertical portion that extends from the upper surface of the first contact layer in the first direction; and
a horizontal portion that extends from the vertical portion toward the channel layer in the second direction,
wherein the inner surface of the channel layer directly contacts a side surface of the horizontal portion.

3. The semiconductor device of claim 2, wherein an upper surface of the horizontal portion of the first contact layer and a lower surface of the vertical portion of the first contact layer are coplanar with each other.

4. The semiconductor device of claim 2, further comprising a vertical insulating layer between the inner surface of the channel layer and a side surface of the vertical portion.

5. The semiconductor device of claim 4, wherein the first contact layer further comprises a doped region that is doped with the impurity of the first conductivity-type, and wherein the doped region extends from the upper surface to a first depth in the first direction.

6. The semiconductor device of claim 5, wherein the first depth of the doped region is less than a length of the vertical insulating layer in the first direction.

7. The semiconductor device of claim 5, wherein the second contact layer is on the channel dielectric layer and is between a side surface of the channel hole and the outer surface of the channel layer.

8. The semiconductor device of claim 7, wherein a length of the second contact layer in the first direction is less than a length of the vertical insulating layer in the first direction.

9. The semiconductor device of claim 2, wherein a lower surface of the second contact layer is separated from the conductive structure by a first distance in the first direction, an upper surface of the horizontal portion of the first contact layer is separated from the conductive structure by a second distance in the first direction, and wherein the first distance is less than the second distance.

10. The semiconductor device of claim 2, wherein a lower surface of the first contact layer is separated from the conductive structure by a first distance in the first direction, a lower surface of an uppermost gate electrode among the gate electrodes is separated from the conductive structure by a second distance in the first direction, and wherein the first distance is greater than the second distance.

11. The semiconductor device of claim 10, wherein the horizontal portion of the first contact layer overlaps an interlayer insulating layer in the second direction and does not overlap the gate electrodes in the second direction, and wherein the interlayer insulating layer is between the gate electrodes.

12. The semiconductor device of claim 1, further comprising a buried insulating layer that is in the channel hole, wherein the first contact layer is on the buried insulating layer.

13. The semiconductor device of claim 1, wherein the conductive structure further comprises:
a resistive contact layer;
a metal barrier layer on the resistive contact layer; and
a metal plate layer on the metal barrier layer,
wherein the resistive contact layer directly contacts each of the first contact layer and the second contact layer.

14. A semiconductor device, comprising:
a stack structure that comprises gate electrodes spaced apart from each other in a first direction, wherein the stack structure defines a channel hole that extends in the first direction, wherein a first width of an upper end of the channel hole in a second direction is greater than a second width of a lower end of the channel hole in the second direction, and wherein the second direction is perpendicular to the first direction;
a conductive structure on the stack structure; and
a channel structure in the channel hole,
wherein the channel structure comprises:
a channel layer that is in the channel hole and extends between the upper end of the channel hole to the lower end of the channel hole; and
a channel pad structure that is in the upper end of the channel hole and is electrically connected to the channel layer and the conductive structure,
wherein the channel pad structure comprises:
a first contact layer that has the first width and comprises an impurity of a first conductivity-type;
a vertical insulating layer that at least partially surrounds a side surface of the first contact layer, wherein the channel layer at least partially surrounds an outer surface of the vertical insulating layer; and
a second contact layer that at least partially surrounds an outer surface of the channel layer and comprises an impurity of a second conductivity-type different from the first conductivity-type,
wherein the first contact layer comprises a portion that extends in the second direction, and
wherein the vertical insulating layer is on and directly contacts the portion of the first contact layer.

15. The semiconductor device of claim 14, further comprising:
a channel dielectric layer between a side surface of the channel hole and the outer surface of the channel layer, wherein the second contact layer is on the channel dielectric layer; and
a buried insulating layer in the channel hole, wherein the first contact layer is on the buried insulating layer.

16. The semiconductor device of claim 14, wherein a thickness of the vertical insulating layer in the second direction is less than or equal to a thickness of the channel layer in the second direction.

17. The semiconductor device of claim 14, wherein:
the first contact layer further comprises a doped region that is doped with the impurity of the first conductivity-type,
the doped region extends from an upper surface of the channel pad structure and to a first depth in the first direction, and
the first depth of the doped region is less than a length of the vertical insulating layer in the first direction.

18. The semiconductor device of claim 14, wherein:
the conductive structure comprises a metal plate layer, and
the first contact layer and the second contact layer are configured to be selectively electrically connected to the channel layer according to the voltage level.

19. A data storage system, comprising:
a semiconductor storage device comprising a first semiconductor structure that comprises circuit elements, a second semiconductor structure on a first surface of the first semiconductor structure, and an input/output pad electrically connected to the circuit elements; and
a controller that is electrically connected to the semiconductor storage device by the input/output pad and is configured to control the semiconductor storage device,
wherein the second semiconductor structure comprises:
a stack structure that comprises gate electrodes spaced apart from each other in a first direction;
a conductive structure on the stack structure
a channel structure that extends into the stack structure and is in a channel hole, wherein an upper end of the channel hole has a first width in a second direction, wherein a lower end of the channel hole has a second width in the second direction, wherein the second direction is perpendicular to the first direction, and wherein the second width is greater than the first width,
wherein the channel structure comprises:
a channel dielectric layer on an inner sidewall of the channel hole;
a channel layer that is on the channel dielectric layer and extends between the upper end of the channel hole and the lower end of the channel hole;
a first contact layer that contacts an inner surface of the channel layer, extends from the upper end of the channel hole in the first direction, and comprises an impurity of a first conductivity-type; and
a second contact layer that contacts an outer surface of the channel layer, extends from the upper end of the channel hole in the first direction, and comprises an impurity of a second conductivity-type different from the first conductivity-type,
wherein each of an upper surface of the first contact layer and an upper surface of the second contact layer contacts a lower surface of the conductive structure.

20. The data storage system of claim 19, wherein the first contact layer further comprises:
a vertical portion that extends from the upper surface of the first contact layer in the first direction; and
a horizontal portion that extends from the vertical portion toward the channel layer in the second direction,
wherein the second semiconductor structure further comprises a vertical insulating layer between the inner surface of the channel layer and a side surface of the vertical portion that is on the horizontal portion.
